(19) United States
(12) Patent Application Publication
(10) Pub. No.: US 2026/0259258 A1
(43) Pub. Date: Sep. 3, 2026

(54) ANALOG CIRCUIT HAVING RECONFIGURATION MEANS FOR A STRESS TEST AND/OR FOR AN IDDQ TEST, AND ASSOCIATED METHODS

(71) Applicant: ELMOS SEMICONDUCTOR SE, Leverkusen (DE)

(72) Inventors: Rüdiger ARNOLD, Berlin (DE); Michal CWIKLINSKI, Falkensee (DE); Lamine HAFIANE, Berlin (DE); Olaf STÖVER, Dortmund (DE); Carsten LEITNER, Berlin (DE); Vadim BARKOW, Dortmund (DE); Christian THUM, Dortmund (DE)

(21) Appl. No.: 19/165,111

(22) PCT Filed: Mar. 22, 2024
(86) PCT No.: PCT/DE2024/100251

§ 371 Date: Sep. 13, 2025

(30) Foreign Application Priority Data
Mar. 22, 2023 (DE) 10 2023 107 250.1

(51) Int. Cl. G01R 31/30; G01R 19/165; G01R 31/28

(52) U.S. Cl. CPC G01R 31/3008; G01R 19/16571; G01R 31/2849; G01R 31/2856

(57) ABSTRACT

An analog circuit fulfills a predetermined circuit purpose in a normal state of the analog circuit. The analog circuit has an analog input or output signal or an analog signal within the analog circuit The analog circuit is coupled to a test logic. The test logic is designed to set the analog circuit to the normal state and at least a first test state. The analog circuit comprises first components designed to perform a function of the analog circuit in accordance with the predetermined circuit purpose during normal operation. The analog circuit further comprises second components designed to enable the test logic to set switching states of the first components in the event of the at least one first test state of the analog circuit of the test logic.

### CROSS REFERENCE TO RELATED APPLICATIONS

This patent application is a national stage of and claims priority to international patent application number PCT/DE2024/100251 filed on Mar. 22, 2024 and which claims the priority and benefit of the German patent application DE 10 2023 107 250.1 dated Mar. 22, 2023, the entire disclosure of which is incorporated herein by reference.

### TECHNICAL FIELD

The disclosure relates to an analog circuit capable of IDDQ testing and/or stress testing.

### BACKGROUND

A key requirement for the use of microelectronic circuits in motor vehicles is high quality and a low failure rate for these circuits. When manufacturing mixed-signal CMOS circuits for the automotive industry, it is, therefore, essential that the microelectronic circuits are tested with sufficient test coverage after manufacture. The IDDQ test is a well-known test for the digital circuit components of such automotive microelectronic circuits.

The IDDQ test is a method for testing integrated CMOS circuits for manufacturing defects. It is based on measuring the supply current (Idd) in the idle state (when the circuit is not switching and the inputs are held at static values). The supply current consumed in this state is generally referred to as the IDDQ quiescent current for the IDD quiescent current. The supply line is often referred to as the VDD line and the associated supply current as the IDD current, hence the name.

The IDDQ test is based on the principle that in a correctly functioning digital CMOS circuit in idle state, there is no static current path between the positive supply voltage line and the negative supply voltage line. At the end of the production of the microelectronic circuit, a fully automatic test device tests the manufactured microelectronic circuit. Typically, the digital circuit parts of the microelectronic circuit are clocked. With each clock edge, circuit nodes within the digital circuit part of the microelectronic circuit change their logical states. These logical states of these circuit nodes are associated with voltage levels of the electrical potential of these circuit nodes relative to a reference node at a reference potential. Since the circuit nodes always have a parasitic node capacitance, this capacitance must be electrically recharged to the new electrical potential when the logical state and thus the electrical potential changes. As a result, an electrical recharge current flows due to the clocking of the digital part of the microelectronic circuit. If the clock is stopped, the circuit nodes in standard CMOS circuits typically maintain their electrical potentials and thus their logic levels, since within the digital part of the microelectronic circuit, each potential current path typically comprises at least one P-channel transistor and one N-channel transistor, one of which is always blocked and the other complementary to it is conductive. Thus, apart from leakage currents after the clock of the digital part of the microelectronic circuit has stopped, no electrical current can flow from the positive supply voltage line of the microelectronic circuit to the negative supply voltage line of the microelectronic circuit via this digital part. The state of the digital part of the microelectronic circuit with the clock switched off is the aforementioned idle state of the digital part of the microelectronic circuit.

In reality, however, a small leakage current flows from the positive supply voltage line of the microelectronic circuit to the negative supply voltage line of the microelectronic circuit via this digital part when the clocks of the digital part are stopped. Normally, this leakage current has a very low, essentially negligible value.

If one of the digital transistors of the digital part has a fault, this very often leads to an increase in its leakage current. This is particularly measurable when it should actually be blocked due to its control. In order to test this transistor, the test device controls the microelectronic circuit with special signal sequences, known as patterns. The transistor to be tested is located in one or more current paths between the positive supply voltage line and the negative supply voltage line. The test vectors that the test system applies to the microelectronic circuit during the test are designed so that when the test system stops clocking, first, the transistor to be tested is blocked at least one time position in the test vectors, and second, at this time position, in at least one of the current paths in which the transistor to be tested is located all other transistors of this current path are switched to conductive.

If the transistor being tested exhibits increased leakage current, an increased leakage current flows between the positive supply voltage line and the negative supply voltage line via this current path. The test system detects the electrical current in one of the two supply voltage lines. The test performed by the test system can use this current value and conclude that one or more transistors are defective if this current value is too high, especially if it exceeds a threshold value. In the event of a fault, the increase in the current value of the leakage current through the transistor under test typically moves by several orders of magnitude compared to the current value for the fault-free case. This makes it possible to detect this fault in the supply current. Another advantage of the IDDQ test is that the test system can check the microelectronic circuit for a relatively large number of possible transistor faults in a relatively large number of transistors with just a few measurements. A further advantage is that the test system can detect faults in transistors that cannot be found with conventional test vectors (patterns) for static faults.

### The IDDQ Test

The IDDQ test is somewhat more complex than simply measuring the supply current. For example, if a line is short-circuited to the positive supply voltage, it will not draw any additional current even if a logic circuit that generates the signal attempts to set it to a high level. However, if the logic circuit then attempts to pull the signal to a low level, there is a sharp increase in leakage current. This increase in the amount of leakage current above a current threshold value signals a faulty component. The test system rejects such faulty components. It is important to note that for IDDQ test inputs, only the controllability of the logic states of the nodes of the digital part is required, but not the observability of these nodes in the sense of logical observability. The observability of the fault effects is achieved via the leakage current by observing and evaluating the current consumption of the supply voltage connections of the circuit.

However, this controllability of the states of the control signals of the transistors in analog circuits is precisely the problem why IDDQ tests are not applicable in analog parts of mixed-signal circuits according to the state of the art. For this reason, mixed-signal circuits often have separate positive analog supply voltage lines that supply the analog part with electrical energy and digital positive supply voltage lines that supply the digital part with electrical energy. Additional circuits enable the analog circuit parts to be separated from the digital circuit parts.

This document explains the problem using a simple differential amplifier stage presented here as an application example for an analog circuit. FIG. 1 shows such an example of an analog circuit 1. However, the principles described here and proposed below can be transferred to other analog circuits.

The voltage source 2 supplies the example analog circuit 1 with electrical energy. A current source 4 draws electrical energy from the supply voltage line 3 and feeds a reference current 5 into a first node 6. The first transistor 7, connected as a MOS diode, takes this reference current 5 from the first node 6 as a reference node and conducts it to the reference potential line 8. The first transistor 7, connected as a MOS diode, converts the reference current 5 into a reference voltage 27. The reference voltage 27 is present between the first node 6 and the reference potential line 8. A second transistor 9 forms a current mirror with the first transistor 7, which is connected as a MOS diode. The second transistor 9, therefore, acts as a current source for the differential stage consisting of the third transistor 10, the fourth transistor 11, the fifth transistor 12, and the sixth transistor 13. The control electrode 28 of the third transistor 10 and the control electrode 29 of the fourth transistor 11 form the differential input of the exemplary differential amplifier. The fifth transistor 12 is connected as a MOS diode and serves as the working resistor of the left amplifier branch consisting of the third transistor 10 and the fifth transistor 12. The sixth transistor 13 is connected as a current source of a current mirror consisting of the sixth transistor 13 and MOS diode 12 and serves as the working resistance of the right amplifier branch consisting of the fourth transistor 11 and sixth transistor 13.

The seventh transistor 15 picks up the signal at the second node 14 between the fourth transistor 11 and the sixth transistor 13 and amplifies the power as part of a source follower circuit consisting of the seventh transistor 15 and the eighth transistor 16. The eighth transistor 16 acts as a current source transistor and thus as the working resistance of the source follower circuit. The eighth transistor 16 is part of a current mirror consisting of the eighth transistor 16 and the first transistor 7 connected as a MOS diode.

An inverter 17 generates an inverted digital transport clock 19 for subsequent transfer gates from a digital transport clock 18.

In the example shown in FIG. 1, a first transfer gate consisting of a ninth transistor 20 and a tenth transistor 21 can charge an intermediate node 25 to the potential of the source follower output 26 when the digital transport clock 18 is at a high level. The inverted digital transport clock 19 is then at a low level. If the digital transport clock 18 is at a low level ( ) and the inverted digital transport clock is, therefore, at a high level, the first transfer gate consisting of the ninth transistor 20 and the tenth transistor 21 blocks. In this case, the intermediate node 25 essentially maintains its voltage level due to parasitic capacitances.

In the example shown in FIG. 1, a second transfer gate consisting of an eleventh transistor 22 and a twelfth transistor 23 can charge an input node 24 of a subsequent analog circuit to the potential of the intermediate node 25 when the digital transport clock 18 is at a high level. The inverted digital transport clock 19 is then at a low level. If the digital transport clock 18 is at a low level and the inverted digital transport clock 19 is, therefore, at a high level, the second transfer gate consisting of the eleventh transistor 22 and the twelfth transistor 23 is blocked. In this case, the input node 24 essentially maintains its voltage level due to parasitic capacitances.

A thirteenth transistor 30 can connect the intermediate node 25 to the reference potential 8.

A first problem now arises in that the reference voltage source consisting of current source 4 and first transistor 7 has a permanent quiescent current due to the MOS diode connection of first transistor 7. Its current value is far above the leakage current of a blocked first transistor 7. The first transistor 7 is, therefore, not accessible to the IDDQ test in the circuit of FIG. 1.

A second problem is that the second transistor 9 always has a reference voltage at its control input, its gate, such that it acts as a current source and, therefore, also has a continuous quiescent current. Its current value is far above the leakage current of a blocked second transistor 9. The second transistor 9 is, therefore, not accessible to the IDDQ test in the circuit of FIG. 1.

A third problem is that the eighth transistor 16 always has a reference voltage at its control input, its gate, such that it operates as a current source and, therefore, also has a continuous quiescent current. Its current value is far above the leakage current of a blocked eighth transistor 16. The eighth transistor 16 is, therefore, not accessible to the IDDQ test in the circuit of FIG. 1.

A fourth problem is that the reference voltage source consisting of the second transistor 9 and the fifth transistor 12 has a permanent quiescent current when the third transistor 10 is switched through due to the MOS diode connection of the fifth transistor 12. The current value of the fifth transistor 12 is typically far above the leakage current of a blocked fifth transistor 12. The fifth transistor 12 is, therefore, not accessible to the IDDQ test in the circuit of FIG. 1.

A fifth problem is that the sixth transistor 13 always has a reference voltage at its control input, its gate, such that it operates as a current source and, therefore, also has a continuous quiescent current. Its current value is far above the leakage current of a blocked sixth transistor 13. The sixth transistor 13 is, therefore, not accessible to the IDDQ test in the circuit of FIG. 1.

A sixth problem is that the seventh transistor 15 always has a voltage at its control input, its gate, such that it is not free of quiescent current. It, therefore, also has a continuous quiescent current. Its current value is far above the leakage current of a blocked seventh transistor 15. The seventh transistor 15 is, therefore, not accessible to the IDDQ test in the circuit of FIG. 1.

Due to the current source function of the second transistor 9, a quiescent current flows through both the third transistor 10 and the fourth transistor 11. Although one of the two transistors can be switched off via the input, the other amplifier branch in supply lines 3 and 8 still generates a quiescent current that is far above the leakage current of the blocked transistors. The third transistor 10 and the fourth transistor 11 are, therefore, not accessible to the IDDQ test in the circuit shown in FIG. 1. For the same reason, the fifth transistor 12 and the sixth transistor 11 in the circuit shown in FIG. 1 are also not accessible to the IDDQ test.

Due to the current source function of the eighth transistor 16, a quiescent current flows through both the eighth transistor 16 and the seventh transistor 15. The seventh transistor 15 and the eighth transistor 16 are, therefore, not accessible to the IDDQ test in the circuit of FIG. 1.

In contrast, the transfer gates are not necessarily traversed by a leakage current. If the output 26 of the source follower and the intermediate node 25 are at the same or essentially the same potential, no electrical leakage current flows through the ninth transistor 20 and the tenth transistor 21. This means that the stimulability of a leakage current through these transistors is already missing for an IDDQ test of the ninth transistor 20 and the tenth transistor 21. The same applies to the eleventh transistor 22 and the twelfth transistor 23. This means that the stimulability of a leakage current through these transistors is also missing for an IDDQ test of the eleventh transistor 22 and the twelfth transistor 23.

However, in the interests of improved functional safety, it is desirable to stress test all transistors in a mixed-signal circuit in an IDDQ test with an increased operating voltage in order to be able to detect imperfectly manufactured transistors and circuit components and, if necessary, activate any faults that have not yet been activated by the stress voltage.

There is, therefore, a current problem with the generation of test vectors for analog parts and a need for the IDDQ test to be applicable to transistors in the analog part of mixed-signal circuits. For the reasons given above, the functional test patterns for large digital control buses of analog parts within mixed-signal circuits generally have far too low test coverage.

Furthermore, unlike with digital circuits, designers cannot generate test patterns for the analog circuit parts fully automatically. Fully automatic test vector generation (abbreviated ATPG) for the analog circuit parts would be very helpful for optimal test coverage. The control signals of the digital part that control the analog part (hereinafter referred to as D2A control signals) must not be freely changed in order to avoid short circuits, damage, and the like.

The static current consumption of the analog part and its dispersion are significantly higher than the expected leakage currents of the transistors in the event of a fault. Specifying a test threshold value for the quiescent current is, therefore, difficult, if not impossible.

Experience has shown that a voltage stress with an impressed increased voltage between the positive supply voltage line 3 of the analog part of the mixed-signal circuit and the reference potential line 8 VDDA places almost no load on the transistors in the analog part. The experiments and investigations carried out during the development of the technical teaching presented here showed a load level of only 2% of the transistors in the analog part. This value can be classified as “untestable.”

The implementation of a bus system from the digital part of a mixed-signal circuit to the analog part of the mixed-signal circuit typically requires a large number of memory cells (latches), which can comprise a large number of transistors in the 5V range and have considerable control electrode areas. In line with a zero-defect strategy, such a large control electrode area should be subjected to a voltage stress test.

US 2005/0024075A1 discloses a device in which faulty states in analog circuits are generated by means of “fault injection transistors,” which allow the detection of faulty states.

However, the technical teaching of US 2005/0024075 A1 does not disclose a method or associated devices that allow an IDDQ test to be performed in accordance with digital circuits.

The technical teaching of US 2005/0024075 A1 discloses the injection of faulty node potentials by means of “fault injection transistors.” In this way, US 2005/0024075 A1 improves the stimulability of the analog circuits to be tested.

However, the technical teaching of US 2005/0024075A1 does not solve the problem of the lack of IDDQ testability of an analog circuit. The circuit examples cited in US 2005/0024075A1 are not fully IDDQ testable. In this context, “fully” refers to an IDDQ test of ALL analog transistors. The technical teaching of US 2005/0024075A1, therefore, solves a completely different problem.

The technical teaching of US 2005/0024075A1 provides for inserting a test block referred to as CUT in US 2005/0024075A1—into the ground connection of an analog CMOS circuit block-referred to as BICS in US 2005/0024075A1—and using it to monitor the operating current of the analog circuit block CUT. However, this is not an IDDQ test as described in US 2005/0024075A1. 0 024 075 A1 as BICS—into the ground supply line of an analog CMOS circuit block and use it to monitor the operating current of the analog circuit block CUT. However, this is not an IDDQ test as understood in test technology.

We quote Wikipedia (found at https://en.wikipedia.org/wiki/Iddq_testing) on this point:

“Iddq testing is a method for testing CMOS integrated circuits for the presence of manufacturing faults. It relies on measuring the supply current (Idd) in the quiescent state (when the circuit is not switching and inputs are held at static values). The current consumed in this state is commonly called Iddq for Idd (quiescent) and hence the name.

Iddq testing uses the principle that in a correctly operating quiescent CMOS digital circuit, there is no static current path between the power supply and ground, except for a small amount of leakage. Many common semiconductor manufacturing faults will cause the current to increase by orders of magnitude, which can be easily detected. This has the advantage of checking the chip for many possible faults with one measurement. Another advantage is that it may catch faults that are not found by conventional stuck-at fault test vectors.

Iddq testing is somewhat more complex than just measuring the supply current. If a line is shorted to Vdd, for example, it will still draw no extra current if the gate driving the signal is attempting to set it to ‘1’. However, a different input that attempts to set the signal to 0 will show a large increase in quiescent current, signaling a bad part. Typical Iddq tests may use 20 or so inputs. Note that Iddq—test inputs require only controllability, not observability. This is because observability is achieved through the shared power supply connection.

The German translation is: “The Iddq test is a method for testing integrated CMOS circuits for the presence of manufacturing defects. It is based on measuring the supply current (Idd) in the idle state (when the circuit is not switching and the inputs are held at static values). The current consumed in this state is commonly referred to as Iddq for Idd (idle current), hence the name.

The Iddq test is based on the principle that in a correctly functioning digital CMOS circuit in idle state, there is no static current path between the power supply and ground, apart from a small amount of leakage current. Many common errors in semiconductor manufacturing cause the current to increase by orders of magnitude, which is easy to detect. This has the advantage that the chip can be checked for many possible errors with a single measurement. Another advantage is that it can detect errors that cannot be found with conventional test vectors for stuck errors.

The Iddq test is somewhat more complex than simply measuring the supply current. For example, if a line is short-circuited to Vdd, it will not draw any additional current even if the gate controlling the signal attempts to set it to ‘1’. However, another input that attempts to set the signal to 0 will show a sharp increase in quiescent current, indicating a bad component. About 20 inputs can be used for typical Iddq tests. Note that only controllability, but not observability, is required for Iddq test inputs. This is because observability is provided via the common power supply connection.

However, the technical teaching of US 2005/0 024 075 A1 still shows static current paths between the positive and negative supply voltages. When US 2005/0024075A1 refers to “IDDQ current” in section [0042], this is not the leakage current of a digital circuit in a static switching state, but the quiescent current of an analog circuit originating from a static current path.

The technical teaching of US 2005/0024075 A1 does not enable the fully automatic generation of IDDQ test patterns. This makes it difficult to verify the corresponding test coverage in circuit designs with functional safety requirements in accordance with ISO 26262.

The technical teaching of US 2005/0024075A1 also does not provide any suggestions on how to deal with feedback branches within the analog circuit.

In the circuit of FIG. 4 of US 2005/0024075A1, an operating current always flows even in a test state, and not just the leakage current of the blocked transistors. US 2005/0024075A1, therefore, does NOT disclose a circuit that is IDDQ testable in any state within the meaning of the document presented here or within the meaning of the Wikipedia definition.

JP 2003156545A discloses a semiconductor chip in which an analog circuit and a digital circuit are integrated. This semiconductor chip is assembled in accordance with the technical teaching of JP 2003156545A. A common power supply connection of the semiconductor chip is used in accordance with the technical teaching of JP 2003156545A to test a semiconductor device that supplies a power supply voltage to the analog circuit and the digital circuit for a current leak in the digital circuit. According to JP 2003156545A, the method of JP 2003156545A consists of interrupting the power supply line from the power supply terminal to the digital circuit at the time of testing and placing the digital circuit in test mode in accordance with JP 2003156545A.

### SUMMARY

The proposal is, therefore, based on the task of creating a solution that does not have the above disadvantages of the prior art and has further advantages.

This task is solved by the technical teaching of the independent claims. Further embodiments are the subject of subclaims, if applicable.

The technical teaching presented here is to use additional switching transistors in a test state of the analog circuit 1 to switch the transistors of the analog part of the mixed-signal so that essentially a CMOS logic circuit is obtained which can be stimulated like a normal CMOS logic circuit with test vectors and for which the IDDQ test vectors can be generated fully automatically by means of an ATPG program.

For this purpose, the technical teaching presented here proposes to provide at least one IDDQ test state for the exemplary analog circuit 1. Furthermore, the technical teaching presented here proposes inserting additional switches into the circuit of the analog circuit elements, which have at least one switching state in normal operation of the exemplary analog circuit 1 and have at least one IDDQ switching state.

The disclosure, therefore, relates to an analog circuit 1 based on MOS, BiCMOS, or CMOS, wherein the analog circuit 1 is designed to fulfill a predetermined circuit purpose in a normal state of the analog circuit 1. The analog circuit 1 has one or more input signals and/or one or more output signals. The analog circuit 1 typically comprises one or more analog signals within the analog circuit 1. The analog circuit 1 is coupled, as proposed, to a test logic 38 which sets the analog circuit 1 to the normal state and, depending on the control of the test logic 38 by an external measuring system, to at least a first test state and/or, if necessary, further test states. The analog circuit 1 comprises first components (7, 9, 10, 11, 12, 13, 15, 16, 20, 21, 22, 23, 30) which perform the function of the analog circuit 1 in accordance with the predetermined circuit purpose of the analog circuit 1 in the normal state of the analog circuit 1. These first components (7, 9, 10, 11, 12, 13, 15, 16, 20, 21, 22, 23, 30), therefore, represent the actual analog circuit 1 or at least essential parts of the analog circuit 1. These first components are preferably MOS transistors or bipolar transistors. Such first components (7, 9, 10, 11, 12, 13, 15, 16, 20, 21, 22, 23, 30) then typically each have a control electrode by means of which the first components (7, 9, 10, 11, 12, 13, 15, 16, 20, 21, 22, 23, 30) can also be operated as switches. The first components (7, 9, 10, 11, 12, 13, 15, 16, 20, 21, 22, 23, 30) can then, in a respective operation as switches, each assume an on state and an off state as respective switching states. In the sense of the document presented here, the first components (7, 9, 10, 11, 12, 13, 15, 16, 20, 21, 22, 23, 30) are completely switched on in the on state, i.e., conductive. Fully switched on means that the conduction resistance (R(ON)resistance) of the first components (7, 9, 10, 11, 12, 13, 15, 16, 20, 21, 22, 23, 30), i.e. the transistors, corresponds to the minimum conduction resistance of these first components (7, 9, 10, 11, 12, 13, 15, 16, 20, 21, 22, 23, 30) with a maximum deviation of less than 25%. The first components (7, 9, 10, 11, 12, 13, 15, 16, 20, 21, 22, 23, 30) are typically completely switched off in the off state, i.e., they are blocking. Completely switched off means that the conduction resistance (R(OFF)resistance) of the first components (7, 9, 10, 11, 12, 13, 15, 16, 20, 21, 22, 23, 30), i.e. the transistors, corresponds to the maximum conduction resistance of these first components (7, 9, 10, 11, 12, 13, 15, 16, 20, 21, 22, 23, 30) with a deviation of less than 25%. Preferably, the analog circuit (1) now comprises second components (S1 to S9; G1 to G9). The test logic 38 uses the second components (S1 to S9; G1 to G9) in the first test state of the analog circuit 1. 22, 23, 30). The control electrode (33, 34, 36, 37) of at least one first component (7, 9, 12, 16) of the first components (7, 9, 10, 11, 12, 13, 15, 16, 20, 21, 22, 23, 30) is not directly connected to an input signal or not directly connected to an output signal. In the prior art, the IDDQ test of such an analog circuit 1 is not described. The test logic 38 now disconnects this control electrode (33, 34, 36, 37) of this first component (7, 9, 12, 16) of the first components (7, 9, 10, 11, 12, 13, 15, 16, 20, 21, 22, 23, 30) from the rest of the analog circuit (1) by means of at least one switch (S1, S2, S3, S4). This causes this control electrode (33, 34, 36, 37, 39) of this first component (7, 9, 12, 16) of the first components (7, 9, 10, 11, 12, 13, 15, 16, 20, 21, 22, 23, 30). It is, therefore, susceptible to influence. However, its potential is not fixed. This means that the switching state of this first component (7, 9, 12, 16) of the first components (7, 9, 10, 11, 12, 13, 15, 16, 20, 21, 22, 23, 30) is also not fixed. In order to specify this switching state, the test logic 38 switches this control electrode (33, 34, 36, 37, 39) of this first component (7, 9, 12, 16) of the first components (7, 9, 10, 11, 12, 13, 15, 16, 20, 21, 22, 23, 30) by means of first means (G1, G2, G5, G6) into an on state or into an off state. In the normal state, the test logic 38 controls these first means (G1, G2, G5, G6) in such a way that these first means (G1, G2, G5, G6) switch the control electrode (33, 34, 36, 37, 39) of this first component (7, 9, 12, 16) of the first components (7, 9, 10, 11, 12, 13, 15, 16, 20, 21, 22, 23, 30) in the normal state of the analog circuit 1. The first means (G1, G2, G5, G6) are, therefore, preferably tri-state drivers whose output switches the first test logic 38 in the normal state to the tri-state state with a high-impedance output resistance and switches it in the first test state to a low-impedance low level or high-level state. The output of the respective tri-state driver is connected to the respective control electrode (33, 34, 36, 37, 39) of a respective first component (7, 9, 12, 16) of the first components (7, 9, 10, 11, 12, 13, 15, 16, 20, 21, 22, 23, 30).

In the normal state, the test logic 38 connects the control electrode (33, 34, 36, 37, 39) of said first component (7, 9, 12, 16) of the first components (7, 9, 10, 11, 12, 13, 15, 16, 20, 21, 22, 23, 30) to a node of the remainder of the analog circuit (1) by means of the switch (S1, S2, S3, S4), thereby ensuring the normal function of the analog circuit 1 in the normal state.

Preferably, the exemplary analog circuit 1 has at least one normal state and a first IDDQ test state and a second IDDQ test state. In the normal state, the exemplary analog circuit 1 performs its intended normal operation. In the first IDDQ test state, all P-channel transistors of the exemplary analog circuit 1 are preferably completely switched on and all N-channel transistors of the exemplary analog circuit 1 are completely switched off. In the second IDDQ test state, all P-channel transistors of the exemplary analog circuit 1 are preferably completely turned off and all N-channel transistors of the exemplary analog circuit 1 are completely turned on.

To enable this, the technical teaching presented here proposes disconnecting all feedback branches by means of feedback switches in the aforementioned first IDDQ test state and in the aforementioned second IDDQ test state.

The disclosure comprises a modified analog circuit that can be manufactured, for example, in MOS, BiCMOS, or CMOS semiconductor technology. For the purposes of this document, semiconductor technologies that are functionally equivalent to such MOS, BiCMOS, or CMOS semiconductor technologies are also included in the term “MOS, BiCMOS, or CMOS.” A semiconductor technology is functionally equivalent if it provides semiconductor switches that have a first connection and a second connection and a control connection, and wherein the semiconductor switch opens or closes the electrical connection between the first connection and the second connection depending on the potential or the input current at the control connection. This definition does not take into account any leakage current.

The technical teaching presented here is intended to refer to analog circuits in general. Preferably, the analog circuit is part of a microintegrated circuit. Such an analog circuit typically fulfills a predetermined circuit purpose in the intended operation of the circuit in which the analog circuit is used. Without limiting the scope of the technical teaching presented here, this predetermined circuit purpose may be, for example, an amplifier, a differential amplifier, a current source, a voltage source, an analog multiplier, an analog multiplexer, an analog filter, an oscillator, a delay line, a phase shifter, an analog PLL, a reset circuit, an electronic fuse, an analog adder, an analog subtractor, an analog diff, an analog integrator, etc., and their interconnections. The present document refers to the following books as examples:
Dietmar Ehrhardt, “Integrated Analog Circuit Technology: Technology, Design, Simulation, and Layout,” June 28, 2000, Vieweg Verlagsgesellschaft; 2000. Edition (June 28, 2000), ISBN-10: 3528038608, ISBN-13: 978-352803860
Phillip E. Allen (author), Douglas R. Holberg, “CMOS Analog Circuit Design,” Oxford University Press; 3rd edition. International (July 13, 2012), ISBN-10: 0199937427, ISBN-13: 978-0199937424
Saggio, Giovanni, Tor Vergata, “Principles of Analog Electronics,” ASIN: 1466582014, Taylor &amp; Francis Inc, January 29, 2014, ISBN-10: 9781466582019, ISBN-13: 978-1466582019
Ulrich Tietze, Christoph Schenk, “Halbleiter-Schaltungstechnik” Hardcover—July 5, 2019, Springer Vieweg; 16th, expanded and updated edition, 2019, ISBN-10: 3662485532, ISBN-13: 978-3662485538

In order for an analog circuit to be considered an analog circuit within the meaning of this document, the analog circuit should have at least one analog input signal or one analog output signal or one analog signal within the analog circuit. Supply voltage lines should expressly not be disregarded when assessing whether a circuit is an analog circuit or not.

For the definition of an analog signal, the present document refers to the state of the art as described on the website https://www.elektronik-kompendium.de/sites/kom/2405151.htm: “An analog signal is a physical quantity that can take on continuous values both in terms of magnitude (amplitude) and over time.

A digital signal (digitus: finger, Latin) is a physical quantity that can only take on certain discrete values. The values correspond to the number of agreed states. If two states are agreed, then these are binary (digital) signals.”

In order for an analog circuit to be considered an analog circuit within the meaning of this document, the analog circuit should have at least one input signal or one output signal or one signal within the analog circuit that can take on continuous values over the course of its magnitude (amplitude) and over time. The magnitude is typically the value of the potential of the line carrying this signal relative to the potential of a reference node of the analog circuit, or the value of the electric current in the line carrying the signal in question.

In particular, the proposed analog circuit is coupled with a test logic (see FIG. 2). As mentioned above, this is preferably a test logic based on the IEEE Standard 1149 with its subvariants. However, it can also be just a scan path that is activated by a test connection from outside the microintegrated circuit.

In particular, the test logic is a digital circuit. In particular, the test logic is designed to set the analog circuit to a normal state and at least a first test state. Preferably, the test logic can set the analog circuit to a normal state and several test states. The different test states serve different test purposes and/or enable the activation of failures of certain parts of the analog circuit in stress tests, for example during a voltage stress test.

The present document refers in this regard to the publication by Ian A. Grout, “Integrated Circuit Test Engineering: Modern Techniques,” Springer London; 2006. Edition, Jun. 2, 2010, ISBN-10: 1846280230, ISBN-13: 978-1846280238.

In particular, the analog circuit according to the disclosure comprises first components that perform the function of the analog circuit in accordance with the purpose of the circuit in normal operation. The interconnection of these first components in the normal state of the analog circuit typically corresponds, at least in part, to a circuit from the prior art. It is conceivable that the principles presented here could also be applied to analog circuits after the disclosure of the technical teaching presented here, which are not yet known in the current state of the art.

In particular, the analog circuit according to the disclosure comprises, in addition to the first components, second components which, in the case of at least one first test state of the analog circuit, enable the test logic to set the switching states of the first components. Preferably, the test logic controls the additional second components.

In an example, the analog circuit according to the disclosure comprises N-channel transistors and P-channel transistors.

In particular, the second components of the test logic in the at least one first test state of the analog circuit enable the switching states of the first components to be set in such a way that, in the first test state, either all N-channel transistors block and all P-channel transistors conduct ( ) or, alternatively, all N-channel transistors conduct and all P-channel transistors block.

Similarly, the analog circuit may have a second test state, which the test logic can set, in which either all N-channel transistors conduct and all P-channel transistors are blocked or, alternatively, all N-channel transistors are blocked and all P-channel transistors conduct.

The second test state would, therefore, preferably be complementary to the first test state in terms of the switching states of the N-channel transistors and the P-channel transistors.

In a further example, the analog circuit according to the disclosure comprises a positive supply voltage line and a negative supply voltage line. As before, the test logic can preferably set the analog circuit to a normal state and at least a first test state. Preferably, the analog circuit also has more than one test state in this further scenario. The above description shall also apply here.

In particular, analog circuit 1 again comprises first components that perform the intended function of the analog circuit in normal operation.

In particular, the analog circuit 1 comprises, in addition to the first components, second components which, in the case of the at least one first test state of the analog circuit, enable the test logic to set the switching states of the first components. This enables a measuring device to control the test logic of the exemplary analog circuit of the exemplary microintegrated circuit, to set the first analog circuit to a test state, and thus to control the switching states of the first components. Preferably, the measuring device can then also control the switching states of the second components. Preferably, the analog circuit behaves like a digital circuit in such a test state. The analog circuit is then accessible in such a test state for the application of methods for testing digital circuits. Therefore, methods for planning the testing of digital circuits, such as fully automatic test pattern generation and/or IDDQ test methods, can then also be applied to the analog circuit in this test state.

In particular, the analog circuit according to the disclosure has several possible current paths from the positive supply voltage line to the negative supply voltage line. These current paths from the positive supply voltage line to the negative supply voltage line of the analog circuit typically comprise components of the first components and/or the second components. Preferably, the analog circuit is designed such that, in the main part of the analog circuit, all first components and/or second components S1 to S9; G1 to G9 are part of at least one such current path. The current paths, therefore, typically and preferably run through these first components and/or through these second components. The second components enable the test logic to set the switching states of the first components in the case of at least one first test state of the analog circuit.

The second components enable the test logic to set the switching states of the first components in the event of at least one first test state of the analog circuit. The test logic preferably sets the switching states of the first components in such a way that at least one first component and/or one second component blocks in each of the possible current paths from the positive supply voltage line to the negative supply voltage line.

If a measuring device now applies an increased supply voltage between the positive supply voltage line and the negative supply voltage line to the analog circuit, this increased voltage is applied across the blocked first components and/or the blocked second components.

This exposes these blocked components to a higher voltage load, which stresses potentially damaged components and typically leads to an increase in the leakage current between the positive supply voltage line and the negative supply voltage line. The measuring device can detect this leakage current later, if necessary, and compare it with a permissible leakage current threshold value. If the value of the leakage current detected by the measuring device is above the leakage current threshold value, the measuring device can conclude that there is a fault, deviation, or quality defect in the analog circuit or something similar and can reject the microelectronic circuit of which the analog circuit is a part. For the sake of clarity, this document refers to faults, deviations, quality defects, and similar issues in the analog circuit collectively as “faults.”

In a further development of the above design, the second components of the test logic enable the switching states of the first components to be set in the case of at least one first test state of the analog circuit, wherein the test logic carries out the setting of the switching states of the first components in such a way that in at least one current path of the analog circuit between the positive supply voltage line and the negative supply voltage line, either exactly one first component and/or exactly one second component is blocked. The present document refers to this current path as the current path under consideration. In the other current paths of the analog circuit between the positive supply voltage line and the negative supply voltage line, which are not the current path under consideration, more than exactly one component can, therefore, block. In the other current paths of the analog circuit between the positive supply voltage line and the negative supply voltage line, which are not the current path under consideration, at least one component of the analog circuit also blocks. Therefore, only a leakage current flows between the positive supply voltage line and the negative supply voltage line of the analog circuit. The other components in this current path under consideration are then not blocked. In the following, this document refers to this one blocking component in the relevant current path as the IDDQ component.

By limiting the component blocking to the IDDQ component in the current path under consideration and switching the other components in the relevant current path to conductive, a measuring device can apply a voltage between the positive supply voltage line and the negative supply voltage line of the analog circuit, which then drops completely across the IDDQ component. If the measuring device increases the voltage between the positive supply voltage line and the negative supply voltage line to the maximum permissible value, it is then ensured that the measuring device loads the IDDQ component to the maximum by means of the applied voltage. This accelerates the aging of the IDDQ component to the maximum. Experience has shown that such loads do not occur cumulatively during the intended service life of the IDDQ component. Experience has shown that properly manufactured IDDQ components are not damaged if the parameters of this load test, for example the value of the applied supply voltage, are selected correctly.

This method allows the measuring device to apply a targeted load to individual components of the analog circuit. The test patterns generated by the test logic are preferably selected so that several components of the analog circuit become IDDQ components with one test pattern. A test pattern is a vector that typically comprises the switching states of the first and second components. By setting a test state, the test logic generates a specific test pattern, whereupon the components of the analog circuit assume the switching states corresponding to this test pattern. At this point, the present document clarifies that this applies to the entire solution proposed in the present document.

By simultaneously setting several components of the analog circuit as IDDQ components of a respective current path, the number of test states required for a complete test of all or most of the components of the analog circuit is reduced.

### BRIEF DESCRIPTION OF THE DRAWINGS

FIG. 1 shows an example of an analog circuit 1.

FIG. 2 shows an example of an analog circuit 1 as proposed, which can be reconfigured in a test state by means of a test logic 38, for example by means of control via a JTAG test bus interface, by suitable “ ” setting of the switching state of additional components (S1 to S9, G1 to G9) so that it is suitable for an IDDQ test and/or a voltage stress test in this reconfigured test state.

FIG. 3 corresponds to FIG. 2, wherein the test logic 38 can now also directly control the switching state of the seventh transistor 15.

FIG. 4 shows a method for performing an IDDQ test of an analog circuit according to FIG. 3.

FIG. 5 shows another method for performing an IDDQ test of an analog circuit according to FIG. 3.

FIG. 6 shows a method for performing an IDDQ test of an analog circuit according to FIG. 2

FIG. 7 shows a method for performing a stress test on an analog circuit according to FIG. 2.

### DESCRIPTION

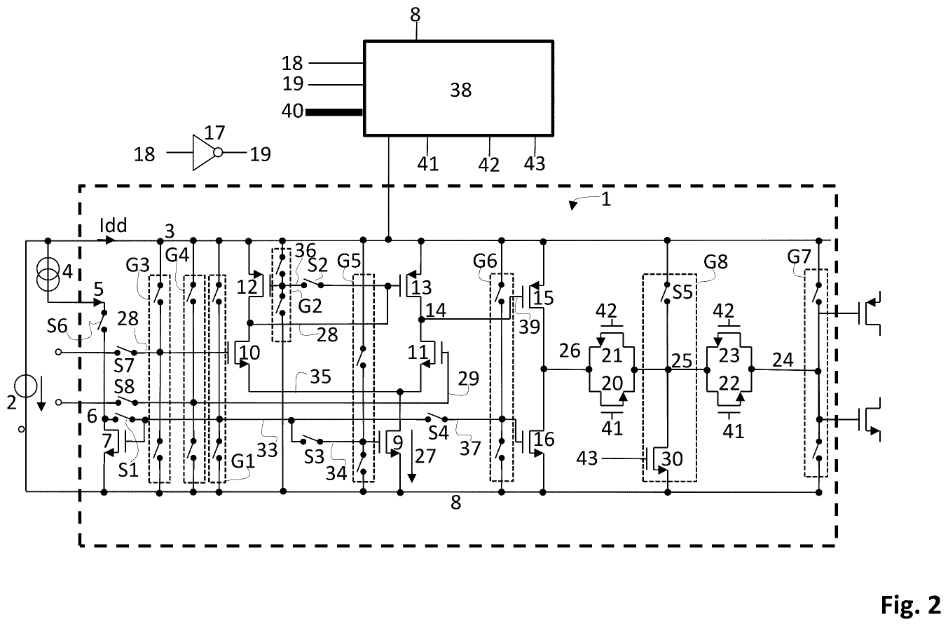

The present document further explains the disclosure with reference to FIGS. 2 to 7, which are provided as examples.

The technical teaching presented here suggests, for the example of the exemplary analog circuit 1, that a MOS diode circuit of a first transistor 7 be disconnected by opening the first switch S1 in the said first IDDQ test state and in the said second IDDQ test state. In the normal state, the first switch S1 is closed, resulting in a MOS diode connection of the first transistor 7. The first switch S1 is thus a feedback switch which is closed in normal operation and open in two test states, namely the first IDDQ test state and the second IDDQ test state. The first switch S1 is preferably a MOS transistor, which is preferably opened or closed via a test logic of the microintegrated circuit, of which the exemplary analog circuit 1 is typically a part. Via the said test logic, a test device can, for example, set normal operation, the first IDDQ test state or the second IDDQ test state. The test logic may, for example, be a JTAG test interface or the like.

### Explanation of the Example

The present document explains the proposal using the example shown in FIG. 2. The example analog circuit 1 in FIG. 2 can explicitly have more than two test states. For the sake of clarity, the present document initially describes only a first IDDQ test state and a second IDDQ test state, without this implying any limitation of the technical teaching presented here.

### Test Logic

The analog circuit 1 shown in FIG. 2 as an example preferably has a test logic 38. The test logic 38 may, for example, be a test interface in accordance with the JTAG boundary scan standard. The document presented here cites, for example, the JTAG standard IEEE 1149. Further information on this can be found, for example, on the Internet at

https://de.wikipedia.org/wiki/Boundary_Scan_Test (NPL1).

A good overview is provided by the document L. Y. Ungar, H. Bleeker, J. E. McDermid and H. Hulvershorn, “IEEE-1149.x standards: achievements vs. expectations,” 2001 IEEE Autotestcon Proceedings. IEEE Systems Readiness Technology Conference. (Cat. No.01CH37237), 2001, pp. 188-205, doi: 10.1109/AUTEST.2001.948964 (NPL2).

The IEEE Standard 1149 comprises several sub-standards:
“IEEE Standard for Boundary-Scan Testing of Advanced Digital Networks,” in IEEE Std 1149.6-2015 (Revision of IEEE Std 1149.6-2003), vol., no., pp. 1-230, March 18, 2016, doi: 10.1109/IEEESTD.2016.7436703. (NPL3)
“IEEE Standard for Reduced-Pin and Enhanced-Functionality Test Access Port and Boundary-Scan Architecture,” in IEEE Std 1149.7-2009, vol., no., pp. 1-985, 10 Feb. 2010, doi: 10.1109/IEEESTD.2010.5412866. (NPL4)
“IEEE Standard for Test Access Port and Boundary-Scan Architecture-Redline,” in IEEE Std 1149.1-2013 (Revision of IEEE Std 1149.1-2001)-Redline, vol., no., pp. 1-899, May 13, 2013. (NPL5)
“IEEE Standard for Test Access Port and Boundary-Scan Architecture,” in IEEE Std 1149.1-2013 (Revision of IEEE Std 1149.1-2001), vol., no., pp. 1-444, May 13, 2013, doi: 10.1109/IEEESTD.2013.6515989. (NPL6)
“IEEE Standard for a Mixed-Signal Test Bus,” in IEEE Std 1149.4-2010 (Revision of IEEE Std 1149.4-1999), vol., no., pp. 1-116, March 18, 2011, doi: 10.1109/IEEESTD.2011.5738198. (NPL7)
“IEEE Standard for Boundary-Scan-Based Stimulus of Interconnections to Passive and/or Active Components,” in IEEE Std 1149.8.1-2012, vol., no., pp. 1-95, Aug. 9, 2012, doi: 10.1109/IEEESTD.2012.6259815. (NPL8)
“IEEE Standard for High-Speed Test Access Port and On-Chip Distribution Architecture,” in IEEE Std 1149.10-2017, vol., no., pp. 1-96, 28 July 2017, doi: 10.1109/IEEESTD.2017.7995164. (NPL9)
“IEEE Standard for Boundary-Scan Testing of Advanced Digital Networks-Redline,” in IEEE Std 1149.6-2015 (Revision of IEEE Std 1149.6-2003)-Redline, vol., no., pp. 1-441, 18 March 2016. (NPL10)
“IEEE Standard for Access and Control of Instrumentation Embedded within a Semiconductor Device,” in IEEE Std 1687-2014, vol., no., pp. 1-283, Dec. 5, 2014, doi: 10.1109/IEEESTD.2014.6974961. (NPL11)
“IEEE Draft Standard for Reduced-Pin and Enhanced-Functionality Test Access Port and Boundary-Scan Architecture,” in IEEE P1149.7/D6, July 2020, vol., no., pp. 1-1043, 3 Nov. 2020. (NPL12)
“IEEE Draft Standard for a Mixed-Signal Test Bus,” in IEEE P1149.4/D2, September 2010, vol., no., pp. 1-113, 7 Oct. 2010. (NPL14)
“IEEE Approved Draft Standard for Test Access Architecture for Three-Dimensional Stacked Integrated Circuits,” in IEEE P1838_D 3.00, September 2019, vol., no., pp. 1-63, 7 Nov. 2019. (NPL15)

For the sake of completeness, this paper also cites the following publication
G. O. D. Acevedo and J. Ramirez-Angulo, “VDDQ: a built-in self-test scheme for analog on-chip diagnosis, compliant with the IEEE 1149.4 mixed-signal test bus standard,” Proceedings of the Fourth IEEE International Caracas Conference on Devices, Circuits and Systems (Cat. No.02TH 8611), 2002, pp. 1026-1026, doi: 10.1109/ICCDCS.2002.1004083. (NPL13)

For clarity, FIG. 2 does not show control lines between the test logic 38 and the tri-state gates (G1 to G9) explained below, the switches (S1 to S9) also explained below, and the other test control lines also explained below.

However, these control lines between the test logic 38 and the tri-state gates (G1 to G9) explained below, the switches (S1 to S9) also explained below, and the other test control lines also explained below are necessary for the function of the technical teaching disclosed here. The figures are, therefore, schematic and simplified.

### Change in the Interconnection of the First Transistor 7

The technical teaching presented here proposes, for the example of the exemplary analog circuit 1, that the MOS diode circuit of the fifth transistor 12 be disconnected by means of a second switch S2 in the said first IDDQ test state and in the said second IDDQ test state by opening the second switch S2. This causes the second switch S2 to disconnect the control electrode 33 of the first transistor 7 from the first node 6. As a result, the potential of the control electrode 33 of the first transistor 7 is undefined after the second switch S2 is opened. However, for an orderly test, such a clear imprint of a unique electrical potential of the control electrode 33 of the first transistor 7 relative to the reference potential of the reference potential line 8 is necessary. In the normal state, the second switch S2 is closed, resulting in a MOS diode connection of the fifth transistor 12 and such a clear potential of the control electrode 33 of the first transistor 7. The second switch S2 is thus a feedback switch which is closed in normal operation and open in the two test states, namely the first IDDQ test state and the second IDDQ test state. The second switch S2 is preferably a MOS transistor which is preferably opened or closed via the test logic of the microintegrated circuit.

### General Treatment of Feedback and Properties of Tri-State Gates

In normal operation, feedback circuits determine the potential of the control electrodes of some transistors in the analog circuit 1. However, when the feedback switches are opened, the potentials of the control electrodes of these transistors are no longer defined.

The document presented here, therefore, proposes connecting these control electrodes preferably to a device that sets the potential of the relevant control electrodes to a defined potential in the event of a first IDDQ test state or a second IDDQ test state and does not influence them in the event of a normal state.

The present document recommends that each of the control electrodes, which are now floating, i.e., undefined in their potential, due to the opening of the feedback switches, be set to a defined potential by means of a tri-state gate, which is usually additional. To simplify the explanation, we assume, for example, that the tri-state gate comprises a first tri-state gate transistor which pulls the output of the tri-state gate to the positive supply potential when it is closed and leaves the output of the tri-state gate unaffected when it is open. To simplify the explanation, let us further assume that the tri-state gate comprises a second tri-state gate transistor which pulls the output of the tri-state gate to the negative supply potential when it is closed and leaves the output of the tri-state gate unaffected when it is open. A control logic ensures that the first tri-state gate transistor and the second tri-state gate transistor are never closed at the same time. The tri-state gate has three states at its output.

In a first state, the output of the tri-state gate is high impedance. In this high-impedance state of the tri-state gate, the first tri-state gate transistor and the second tri-state gate transistor are open in the example. Thus, the tri-state gate does not influence the node at its output in the first state.

In a second state, the output of the tri-state gate is connected to the negative supply voltage line. In this high-impedance state of the tri-state gate, the first tri-state gate transistor is open and the second tri-state gate transistor is closed in the example.

In a third state, the output of the tri-state gate is connected to the positive supply voltage line. In this high-impedance state of the tri-state gate, the first tri-state gate transistor is closed and the second tri-state gate transistor is open in the example.

### Implementation in the Example Analog Circuit 1

The document presented here, therefore, proposes inserting a first switch S1 into the reference voltage line of the first node 6. The test logic 38 controls the first switch S1. For clarity, the exemplary FIG. 2 does not show these control lines from the test logic 38 to the first switch S1. If the exemplary analog circuit 1 is in the normal state, the test logic 38 closes the first switch S1. If the exemplary analog circuit 1 is in the first IDDQ test state or in the second IDDQ test state, the test logic 38 opens the first switch S1 and thus disconnects the feedback of the first transistor 7 to itself.

The present document further proposes connecting the control electrode 33 of the first transistor 7 to the output of a first tri-state gate G1. The test logic 38 controls the first tri-state gate G1. For clarity, the exemplary FIG. 2 does not show these control lines from the test logic 38 to the first tri-state gate G1. The test logic 38 is thus able to impose a defined logic level on the control electrode 33 of the first transistor 7 by means of the first tri-state gate G1 when the exemplary analog circuit 1 is in the first IDDQ test state or in the second IDDQ test state and the first switch S1 is, therefore, open. If the exemplary analog circuit 1 is in the normal state, the test logic 1 switches the first tri-state gate G1 to high impedance. If the exemplary analog circuit 1 is in the normal state, the first tri-state gate G1 ideally behaves as if it does not exist and does not interfere with the analog circuit function of the exemplary analog circuit 1.

If the exemplary analog circuit 1 is in the first IDDQ test state or in the second IDDQ test state, the first tri-state gate G1 ideally sets the potential at the control electrode 33 of the first transistor 7. If the example analog circuit 1 is in the first IDDQ test state or in the second IDDQ test state, the first tri-state gate G1 ideally determines the switching state of the first transistor 7.

The document presented here, therefore, also proposes connecting the control electrode 36 of the fifth transistor 12 to the output of a second tri-state gate G2. The test logic 38 controls the second tri-state gate G2. For clarity, the example figure does not show these control lines from the test logic 38 to the second tri-state gate G2. The test logic 38 is thus able to impose a defined logic level on the control electrode of the fifth transistor 12 when the exemplary analog circuit 1 is in the first IDDQ test state or in the second IDDQ test state and the second switch S2 is, therefore, open.

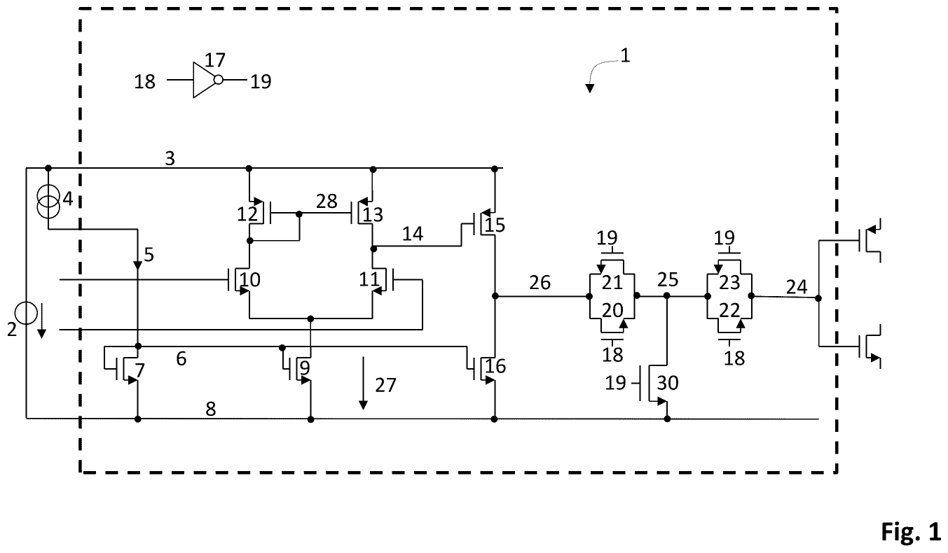

In the example of FIG. 1, the control electrode 28 of the third transistor 10 is to be an external input of the exemplary analog circuit 1.

In the example of FIG. 1, the control electrode 29 of the fourth transistor 11 is to be an external input of the exemplary analog circuit 1.

The present document, therefore, proposes connecting the control electrode 28 of the third transistor 10 to the output of a third tri-state gate G3. The test logic 38 preferably controls the third tri-state gate G3. For clarity, the exemplary FIG. 2 does not show these control lines from the test logic 38 to the third tri-state gate G3. The test logic 38 is thus able to impose a defined logic level on the control electrode 28 of the third transistor 10 when the exemplary analog circuit 1 is in the first IDDQ test state or in the second IDDQ test state. Preferably, a seventh switch S7 is inserted into the line of the control electrode 28 of the third transistor 10, which disconnects the control electrode 28 of the third transistor 10 and the feed point of the third tri-state gate G3 on one side of the seventh switch S7 from the third node 31 on the other side of the seventh switch S7 when the exemplary analog circuit 1 is in the first IDDQ test state or in the second IDDQ test state. The seventh switch S7 is then preferably open. In the normal state, the seventh switch S7 is then preferably closed and preferably connects the third node 31 to the control electrode 28 of the third transistor 10. It is, therefore, conceivable to insert this seventh switch S7 into the line of the control electrode 28 of the third transistor 10, which disconnects this input of the third node 31 from the feed point of the third tri-state gate G3 and the control electrode 28 of the third transistor 10 when the exemplary analog circuit 1 is in the first IDDQ test state or in the second IDDQ test state, and which connects this input of the third node 31 to the feed point of the third tri-state gate G3 and the control electrode 28 of the third transistor 10 when the exemplary analog circuit 1 is in the normal state. Preferably, the test logic 38 controls this additional seventh switch S7.

The document presented here also proposes connecting the control electrode 29 of the fourth transistor 11 to the output of a fourth tri-state gate G4. The test logic 38 controls the fourth tri-state gate G4. For clarity, the exemplary FIG. 2 does not show these control lines from the test logic 38 to the fourth tri-state gate G4. The test logic 38 is thus able to impose a defined logic level on the control electrode 29 of the fourth transistor 11 when the exemplary analog circuit 1 is in the first IDDQ test state or in the second IDDQ test state. Preferably, an eighth switch S8 is inserted into the line of the control electrode 29 of the fourth transistor 11, which disconnects the control electrode 29 of the fourth transistor 11 and the feed point of the fourth tri-state gate G4 on one side of the eighth switch S8 from the fourth node 32 on the other side of the eighth switch S8 when the exemplary analog circuit 1 is in the first IDDQ test state or in the second IDDQ test state. The eighth switch S8 is then preferably open. In the normal state, the eighth switch S8 is then preferably closed and preferably connects the fourth node 32 to the control electrode 29 of the fourth transistor 11. It is, therefore, conceivable to insert an eighth switch S8 into the line of the control electrode 29 of the fourth transistor 11, which disconnects this input of the fourth node 32 from the feed point of the fourth tri-state gate G4 on the one hand and from the control electrode 29 of the fourth transistor 11 on the other hand when the exemplary analog circuit 1 is in the first IDDQ test state or in the second IDDQ test state, and which connects this input of the fourth node 32 to the feed point of the fourth tri-state gate G4 and the control electrode 29 of the fourth transistor 11 when the exemplary analog circuit 1 is in the normal state. Preferably, the test logic controls this additional switch.

### Separation of Electrically Interconnected Circuit Nodes

The present document also proposes separating control electrodes of the exemplary analog circuit 1 that are electrically connected to one another by means of additional switches when the exemplary analog circuit is in an IDDQ test state, in particular in the first IDDQ test state or in the second IDDQ test state.

In the example shown in FIG. 1, the control electrode of the first transistor 7, the control electrode of the second transistor 9, and the control electrode 37 of the eighth transistor 16 are connected to each other via the first node 6, which is a reference voltage line.

FIG. 2 shows the modifications that the present document proposes as examples in this regard.

By way of example, the present document proposes that the test logic 38 preferably disconnects the control electrode 34 of the second transistor 9 from the first node 6 by means of a third switch S3 when the exemplary analog circuit 1 is in the first IDDQ test state or in the second IDDQ test state, and that the test logic 38 preferably connects the control electrode 34 of the second transistor 9 to the first node 6 by means of the third switch S3 when the exemplary analog circuit 1 is in the normal state. The test logic 38, therefore, preferably closes the third switch S3 when the exemplary analog circuit 1 is in the normal state and preferably opens the third switch S3 when the exemplary analog circuit is in the first IDDQ test state or in the second IDDQ test state. The test logic 38 preferably controls the third switch S3. For clarity, the exemplary FIG. 2 does not show these control lines from the test logic 38 to the third switch S3.

By way of example, the present document suggests that the test logic 38 preferably disconnects the control electrode 37 of the eighth transistor 16 from the first node 6 by means of a fourth switch S4 when the exemplary analog circuit 1 is in the first IDDQ test state or in the second IDDQ test state, and that the test logic 38 preferably connects the control electrode 37 of the eighth transistor 16 to the first node 6 by means of a fourth switch S4 when the exemplary analog circuit 1 is in the normal state. The test logic 38, therefore, preferably closes the fourth switch S4 when the exemplary analog circuit 1 is in the normal state and preferably opens the fourth switch S4 when the exemplary analog circuit is in the first IDDQ test state or in the second IDDQ test state. The test logic 38 preferably controls the fourth switch S4. For clarity, the exemplary FIG. 2 does not show these control lines from the test logic 38 to the fourth switch S4.

So that the control electrode 37 of the second transistor 9 does not have an undefined potential in the first IDDQ test state or in the second IDDQ test state, the present document proposes connecting the control electrode 37 of the second transistor 9 to the output of a fifth tri-state gate G5. The test logic 38 preferably controls the fifth tri-state gate G5. As a result, the test logic 38 is typically able to impose a defined logic level on the control electrode 37 of the second transistor 9 when the exemplary analog circuit 1 is in the first IDDQ test state or in the second IDDQ test state and the third switch S3 and the first switch S1 and the fourth switch S4 are, therefore, open.

### Indirect Control of Switch States

Since the test logic 38 in the first IDDQ test state or in the second IDDQ test state of the exemplary analog circuit 1 typically controls the switching states of the second transistor 9, the third transistor 10, the fourth transistor 11, and the fifth transistor 12, the test logic 38 can also control the switching state of the sixth transistor 13 in the first IDDQ test state or in the second IDDQ test state. The reason for this is that the test logic 38 can typically set the potential of the control electrode 28 of the sixth transistor 13 by setting the switching states of the second transistor 9, the third transistor 10, the fourth transistor 11, and the fifth transistor 12. This typically allows the test logic 38 to set the switching state of the sixth transistor 13 by setting the switching states of the second transistor 9, the third transistor 10, the fourth transistor 11, and the fifth transistor 12.

Since the test logic 38 can control the switching state of the sixth transistor 13 and the fourth transistor 11 in the first IDDQ test state or in the second IDDQ test state, the test logic 38 can typically also check the switching state of the seventh transistor 15 in the first IDDQ test state or in the second IDDQ test state. The reason for this is that typically, the test logic 38 can check the switching state of the sixth transistor 13 and the fourth transistor 11 in the first IDDQ test state or in the second IDDQ test state, the test logic 38 in the first IDDQ test state or in the second IDDQ test state can typically also check the potential of the second node 14 and thus typically also the potential of the control electrode 39 of the seventh transistor 15.

Since the test logic 38 can check the switching state of the seventh transistor 15 and the eighth transistor 16 in the first IDDQ test state or in the second IDDQ test state, the test logic 38 can also control the potential of the output of the source follower 26 from the seventh transistor 15 and the eighth transistor 16 in the first IDDQ test state or in the second IDDQ test state.

### Handling of Intermediate Nodes

Analog circuits typically also include switches that are intended to pull a node such as the intermediate node 25 to a supply voltage potential or the like under certain conditions in normal operation. In the case of the exemplary analog circuit 1 of FIG. 1, the thirteenth transistor 30 is such a transistor.

Such a transistor is connected on one side to a supply voltage line of a first polarity and on the other side to a node of the exemplary electrical side. The present document proposes providing an additional switch that can connect the relevant node to the other supply voltage line.

The present document proposes that the control of such a transistor and the additional switch be designed such that, in the normal state of the exemplary analog circuit, the additional switch is open and the transistor operates normally in dependence on the other control signals 40 of the overall circuit, as if the modification did not exist. However, in the first IDDQ test state or in the second IDDQ test state of the exemplary analog circuit 1, the additional switch and the transistor operate as a tri-state gate so that the test logic can control the voltage level of the node.

The exemplary thirteenth transistor 30 is such a transistor. The thirteenth transistor 30 of the exemplary analog circuit 1 is connected on one side to a supply voltage line 8 of a first polarity and on the other side to the intermediate node 25 of the exemplary analog circuit 1. The present document proposes providing an additional fifth switch S5 that can connect the relevant intermediate node 25 to the other supply voltage line.

The present document proposes that the control of the thirteenth transistor 30 and the additional fifth switch S5 by the test logic 38 be designed such that that in the normal state of the exemplary analog circuit 1, the additional fifth switch S5 is open and the thirteenth transistor 30 operates normally in dependence on the other control signals of the overall circuit, as if the modification did not exist.

Specifically, this may mean, for example, that in the example of FIG. 2, the digital transport clock 18 is an input signal of the test logic 38 and that in the normal state of the exemplary analog circuit 1, the digital transport clock 18 is equal to the modified digital transport clock 41 and that in the first IDDQ test state or in the second IDDQ test state, the test logic 38 typically generates the modified digital transport clock 41 independently of the digital transport clock 18. Furthermore, this can mean, for example, that in the example of FIG. 2, the inverted digital transport clock 19 is an input signal of the test logic 38 and that in the normal state of the exemplary analog circuit 1, the inverted digital transport clock 19 is equal to the modified inverted digital transport clock 42 and that in the first IDDQ test state or in the second IDDQ test state, the test logic 38 typically generates the modified inverted digital transport clock 42 independently of the inverted digital transport clock 19.

However, in the first IDDQ test state or in the second IDDQ test state of the exemplary analog circuit 1, the additional fifth switch S5 and the thirteenth transistor 30 work together as an eighth tri-state gate G8, so that the test logic 38 can preferably control the voltage level of the intermediate node 25. For this purpose, the test logic 38 preferably controls the potential of the control electrode 43 of the thirteenth transistor 30 ( ). This means that the test logic preferably controls the switching state of the thirteenth transistor 30. In the example of FIG. 2, in the normal state of the exemplary analog circuit 1, the signal of the control electrode 43 of the thirteenth transistor 30 is preferably equal to the inverted digital transport clock 19. In the first IDDQ test state and in the second IDDQ test state, the test logic 38 typically generates the signal of the control electrode 43 of the thirteenth transistor 30 independently of the inverted digital transport clock 19.

In the example analog circuit 1 of FIG. 2, the ninth transistor 20 and the tenth transistor 21 form a so-called transfer gate, which connects the intermediate node 25 to the source follower from the seventh transistor 15 and eighth transistor 16 when the control electrodes of the ninth transistor 20 and the tenth transistor 21 are driven appropriately. In the example of FIG. 2, the test logic 38 generates the modified digital transport clock 41 such that the modified digital transport clock 41 is equal to the digital transport clock 18 when the exemplary analog circuit 1 is in the normal state, and that the test logic 38 generates the modified digital transport clock 41 independently of the digital transport clock 18 when the exemplary analog circuit 1 is in the first IDDQ test state or in the second IDDQ test state.

Preferably, the test logic 38 then controls the control electrodes of the ninth transistor 21 and the tenth transistor 21 and the twelfth transistor 23 and the eleventh transistor 22 and the thirteenth transistor 30 independently of one another, whereby the test logic 38 prevents and locks uncontrolled cross currents. In the first IDDQ test state or in the second IDDQ test state of the exemplary analog circuit 1, the test logic 38 can typically control the switching states of the seventh transistor 15 and the eighth transistor 16 and the thirteenth transistor 30 and the ninth transistor 20 and the tenth transistor 21 and the fifth switch S5 such that no cross-current occurs there either.

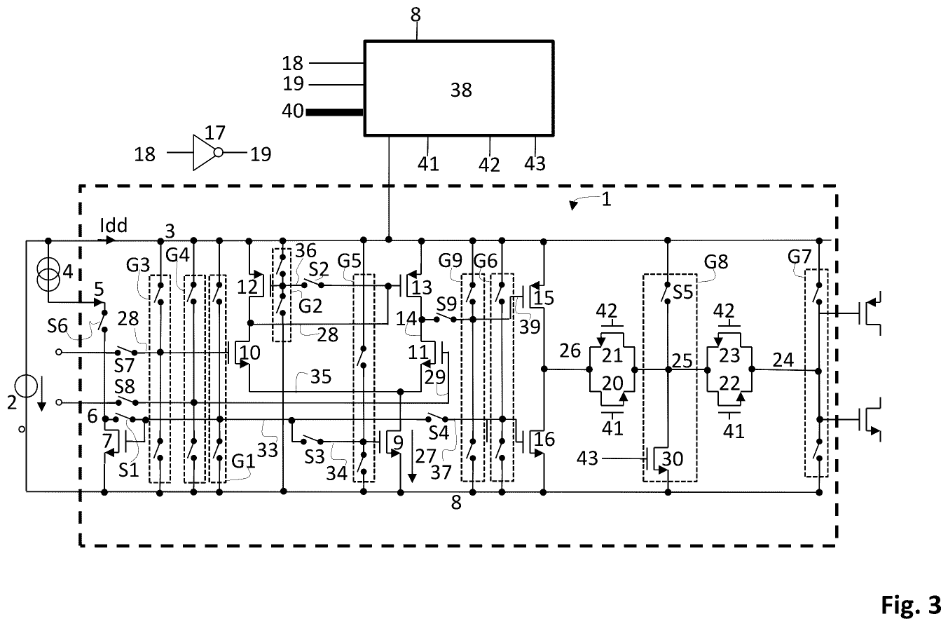

FIG. 3 essentially corresponds to FIG. 2, with the difference that a ninth switch S9 can disconnect the second node 14 from the control electrode 39 of the seventh transistor 15.

By way of example, the present document suggests that the test logic 38 preferably disconnects the control electrode 39 of the seventh transistor 15 from the second node 14 by means of an additional ninth switch S9 when the exemplary analog circuit 1 is in the first IDDQ test state or in the second IDDQ test state, and that the test logic 38 preferably connects the control electrode 39 of the seventh transistor 15 to the fourth node 6 by means of the ninth switch S9 when the exemplary analog circuit 1 is in the normal state. The test logic 38, therefore, preferably closes the ninth switch S9 when the exemplary analog circuit 1 is in the normal state and preferably opens the ninth switch S9 when the exemplary analog circuit is in the first IDDQ test state or in the second IDDQ test state. The test logic 38 preferably controls the ninth switch S9. For clarity, the exemplary FIG. 3 does not show these control lines from the test logic 38 to the ninth switch S9.

So that the control electrode 39 of the seventh transistor 15 does not have an undefined potential in the first IDDQ test state or in the second IDDQ test state, the present document proposes connecting the control electrode 39 of the seventh transistor 15 to the output of a ninth tri-state gate G9. The test logic 38 preferably controls the ninth tri-state gate G9. This typically enables the test logic 38 to impose a defined logic level on the control electrode 39 of the seventh transistor 15 when the exemplary analog circuit 1 is in the first IDDQ test state or in the second IDDQ test state and the ninth switch S9 is open. This means that the test logic 38 is typically also able to control the switching state of the seventh transistor 15 when the exemplary analog circuit 1 is in the first IDDQ test state or in the second IDDQ test state and the ninth switch S9 is open.

This simplifies the generation of test patterns, since the test logic 38 no longer has to generate and set pattern sequences from a predetermined temporal sequence of several patterns. This simplifies the test pattern generation for generating the sequence of patterns to be set by the test logic 38. This shortens the test time by the measuring device, which represents an economic advantage.

In a transfer gate with a first transfer gate connection and a second transfer gate connection, the test logic 38 can, therefore, preferably check the potentials at the first transfer gate connection and a second transfer gate connection in the first IDDQ test state or in the second IDDQ test state by means of at least one additional switch-here the fifth switch S5. In this context, “check” preferably means that the test logic 38 can apply a voltage equal to the operating voltage to the transfer gate by controlling the transfer gate and the transistors and switches that determine the potential at the first transfer gate connection and at the second transfer gate connection, whereby the direction of the voltage across the transfer gate can preferably be specified by the test logic.

The example of analog circuit 1 in FIG. 2 now provides that the test logic 38 can also connect the analog output 24 of the exemplary analog circuit 1 to the positive supply voltage or the negative supply voltage via a seventh tri-state gate G7 in the first IDDQ test state or in the second IDDQ test state. In the normal state of the example analog circuit 1 in FIG. 2, the output of the seventh tri-state gate G7 is preferably high impedance, since the switches of this seventh tri-state gate G7 are then typically open.

### Voltage Stress Load for Activating Previously Damaged Components

In the first example embodiment of the proposal, the transistors of the example analog circuit 1 are to be subjected to a maximum voltage stress before the actual IDDQ test in order to reveal latent defects in the transistors. Typically, such latent defects do not cause failures in previous functional tests because the transistors are functioning. The voltage stress, which perfectly manufactured transistors can withstand without damage, further damages such pre-damaged transistors, so that the stress test amplifies the effects of the thus increased damage in the production test to such an extent that a measuring device for measuring the exemplary analog circuit 1 can detect them.

In this first example embodiment, the present document proposes, for example, that in a first test step, the measuring device uses test logic 38 in the first IDDQ test state of the exemplary analog circuit 1 to switch all P-channel transistors of the exemplary analog circuit 1 to conductive and all N-channel transistors to non-conductive. The measuring device raises the supply voltage to the maximum permissible level for a time that is just permissible. This leads to damage to pre-damaged transistors of the exemplary analog circuit 1. However, this does not lead to damage to non-pre-damaged transistors of the exemplary analog circuit 1. The maximum permissible time for such a stress load depends on the semiconductor or CMOS technology used. The maximum permissible time should preferably be determined during the development of the semiconductor or CMOS technology or during the qualification of the component for the technical teaching disclosed herein by means of stress tests on a sufficient number of components with preferably typical control of the manufacturing parameters in manufacturing tests and stress tests.

In this first exemplary embodiment, the present document proposes, for example, that in a second test step, the measuring device switches all N-channel transistors of the exemplary analog circuit 1 to the conducting state and all P-channel transistors to the blocking state by means of the test logic 38 in the second IDDQ test state of the exemplary analog circuit 1. The measuring device raises the supply voltage to the maximum permissible level for a just permissible time. This leads to damage to pre-damaged transistors of the exemplary analog circuit 1. However, this does not lead to damage to non-pre-damaged transistors of the exemplary analog circuit 1.

If not all P-channel transistors and/or not all N-channel transistors can be brought into the intended switching state, additional switches or tri-state gates are inserted in the design to isolate the control nodes of these transistors in the first IDDQ test state and in the second IDDQ test state from other nodes and to be able to control them in accordance with the above examples.

For the purposes of this document, the measuring device and/or the test process of analog circuit 1 can, for example, perform the first step and the second step individually or sequentially in any order.

### Leakage Current Measurement of Individual Transistors

In a second exemplary embodiment of the proposal, the measuring device applies a typically increased supply voltage to the exemplary analog circuit 1. The measuring device then brings the exemplary analog circuit 1 into different test states one after the other by means of the test logic 38. In each test state of the exemplary analog circuit 1, the test logic 38 typically sets the switching states of the transistors, switches, and tri-state gates of the exemplary analog circuit 1 differently. In the following, we refer to the vector of the switching states of these elements of the exemplary analog circuit 1, i.e., the transistors, switches, and tri-state gates of the exemplary analog circuit 1, as a pattern. The difference between two different patterns can, therefore, only affect the switching state of a single transistor or a single switch or a single tri-state gate of the exemplary analog circuit 1 between these two patterns. Typically, however, with two different patterns, at least two switching states of at least two of these elements are different between these patterns. A developer of a production test will typically select the patterns so that only the leakage current can flow in each test state of these test states. To do this, the developer designs the control signals of the measuring device so that the test logic generates the patterns for controlling the transistors, switches, and tri-state gates in such a way that at least one transistor or one switch blocks at least one of the current paths between the positive supply voltage and the negative supply voltage, and no cross-current flows from the positive supply voltage line to the negative supply voltage line in the exemplary analog circuit 1. A cross-current in the sense of the present document is thus typically a short-circuit current from the positive supply voltage line 3 of the exemplary analog circuit 1 to the negative supply voltage line 8 or an equivalent fault current. Preferably, in each test state of these test states, the test logic 38 should control the transistors, switches and tri-state gates in such a way that at least one transistor or at least one switch is blocked in at least one current path between the positive supply voltage line and the negative supply voltage line or their function equivalents, and the other transistors and switches of this current path are open. In all other possible current paths between the positive supply voltage line and the negative supply voltage line and their functional equivalents, at least one switch is open or at least one transistor is blocked so that no current can flow there either. The switches may also be switches within the tri-state gates. This blocking transistor or blocking switch is referred to in the present document as the “IDDQ-tested transistor” for this test state. The measuring device now sets test state after test state in chronological order using the test logic 38. The test logic 38 preferably sets a test state-specific pattern for each test state. The measuring device preferably determines the leakage current for each test state. The leakage current is typically the current consumption of the exemplary analog circuit 1, preferably via the supply voltage lines. The measuring device compares these detected leakage current values of the leakage currents of the various test states with a specified value. The specified value can be global or specific to groups of test states or specific to the respective test states. Mixtures of test states are conceivable. The current consumption of the exemplary analog circuit 1 is typically the leakage current of the IDDQ-tested transistors of the respective test states. Preferably, the measuring device changes the test states in the form of the patterns generated by the test logic 38 until all transistors and switches of the exemplary analog circuit 1 have been an IDDQ-tested transistor at least once. In a preferred embodiment, the measuring device can, for example, control the test logic 38 via a JTAG test bus interface. The advantage of this method in conjunction with the switches and tri-state gates of the exemplary analog circuit 1 is that, firstly, the leakage current of each transistor can be detected and, secondly, a maximum voltage stress can be applied to each transistor when the measuring device detects the leakage current of the transistor. In addition, the test patterns for generating the control signals of the logic 38 for setting the patterns can be generated using ATPG methods. The test logic 38 should reliably prevent cross currents.

The test procedure preferably consists of an initial stress test, which uses the first version of the proposal to induce maximum acceleration of latent faults by applying maximum supply voltage, and optionally a subsequent systematic measurement of the leakage currents of all transistors using one or more IDDQ measurements, if necessary, using different patterns.

Incidentally, it has been shown that in many cases it is sufficient to perform only the stress test using the method of the first embodiment of the proposal and then measure the current consumption of the exemplary analog circuit 1 in normal operation. However, this measurement method is less precise.

The present document proposes combining the test of the exemplary analog circuit 1 with the digital test using the measuring device. To enable this, the present document proposes integrating digital flip-flops (memory cells) into the scan path of the test logic 38 in one or more or all test states. These digital flip-flops thereby block the signals from and to analog circuit 1 in these test states. In simple terms, the “doors” to the exemplary analog circuit are thus closed and under the control of test logic 38, which may control these digital flip-flops or of which these digital flip-flops may be a part.

The measuring device preferably sets the test states and the patterns via the scan path of the test logic 38 and controls the test logic 38 accordingly.

During the measurements in the test states with stopped clocks, the supply current of the exemplary analog circuit should typically be close to “zero” in the various test states with different patterns. Practical tests during the development of the proposal presented here have shown that the use of automatically generated IDDQ test patterns with approx. 20 IDDD measurement points produces very good results.

The elaboration of the proposal presented here has shown that a voltage stress with a gate voltage typically increased for a period of 20 months already destroys weak transistors. A noticeable increase in leakage current can then be measured. These voltage surge levels and the duration of the surge depend greatly on the specific analog circuit technology or CMOS technology in which analog circuit 1 is implemented.

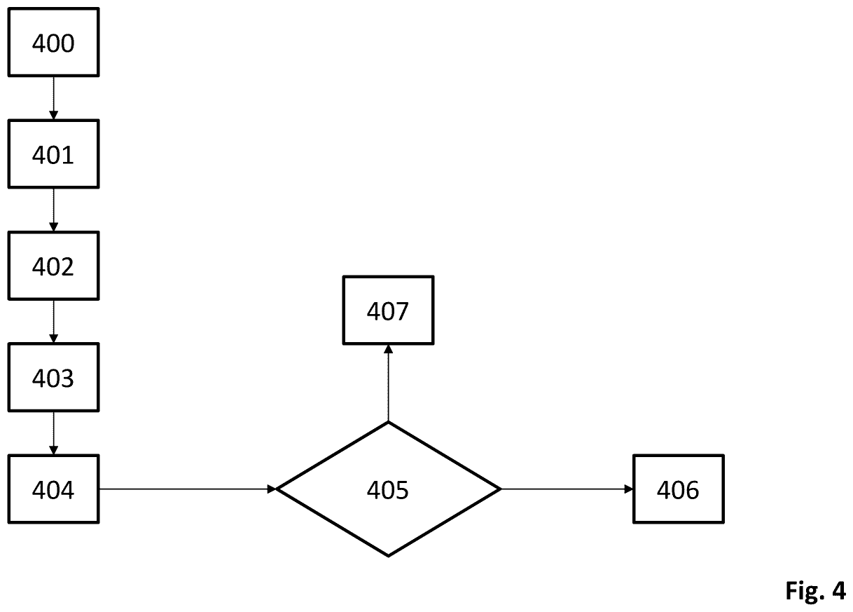

The present document proposes a method for performing an IDDQ test on an analog circuit 1 to solve the above problem. FIG. 4 illustrates the method schematically and in simplified form. The analog circuit 1 is, for example, an analog circuit 1 corresponding to the design shown in FIG. 3.

The method proposed here comprises several steps.

If no measuring device is available, the method begins with step 400 of providing a measuring device.

In the next step, the analog circuit 1 is supplied with electrical energy, preferably by the measuring device.

In the next step, the analog circuit 1 is transferred 402 to the first test state, with the measuring device preferably performing this transfer by means of the test logic 38, for example via a JTAG test bus interface.

In the next step, the current consumption of the analog circuit 1 in this first test state is detected 403 and a current consumption value is determined, in particular by means of the measuring device, which preferably detects a value of the electric current that it feeds into one of the supply voltage lines 3, 8 of the analog circuit 1.

In the next step, the recorded current consumption value is compared 404 with a specified value, with the said measuring device preferably performing this comparison.

In the next step, a fault is detected 405 if the current consumption value is greater than the specified value, with the said measuring device preferably performing this detection and then preferably rejecting 406 the analog circuit 1, which may be faulty, in the event of such a fault.

If the measuring device does not indicate an error in analog circuit 1 in the preceding step 405, analog circuit 1 can be used as intended with a higher degree of probability 407 if analog circuit 1 is not rejected for other reasons in further, subsequent, or preceding tests.

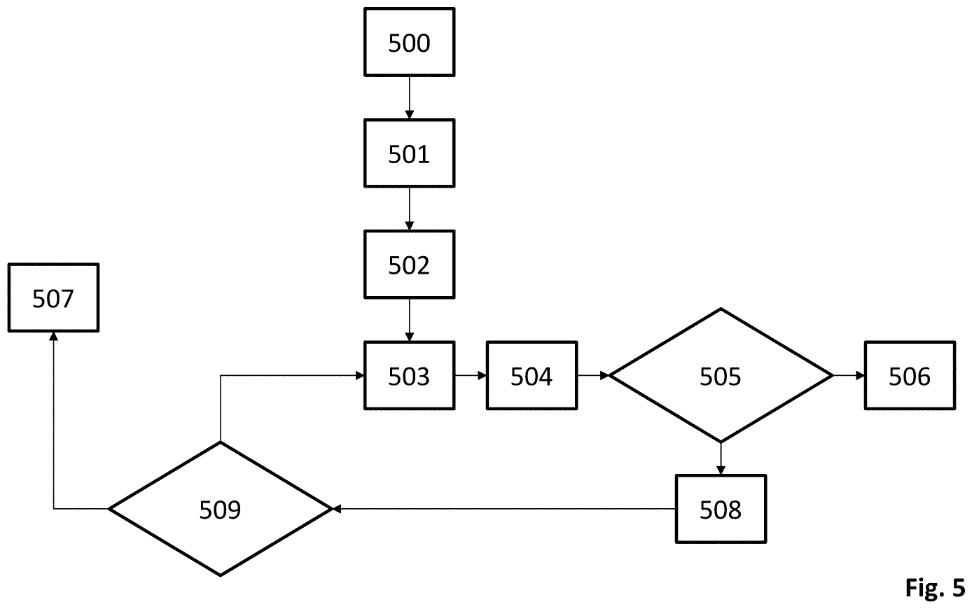

The present document proposes a further method for performing an IDDQ test on an analog circuit 1 to solve the above problem. FIG. 5 illustrates the method in a simplified schematic form. The analog circuit 1 is, for example, an analog circuit 1 corresponding to the embodiment shown in FIG. 3.

The analog circuit 1 should now, as an example, have one or more additional test states in addition to the first test state shown in FIG. 3, deviating from the design shown in FIG. 3.

This document collectively refers to these additional test states and the first test state mentioned above as “test states.”

These test states should preferably now differ in that at least one IDDQ component of one test state of the test states differs from all other IDDQ components of all other test states.

Thus, this IDDQ component of the test state differs from any other IDDQ components of the other test states.

The method proposed here comprises several steps.

If no measuring device is available, the method begins with step 500 of providing a measuring device.

In the next step, the analog circuit 1 is supplied with electrical energy, preferably by the measuring device.

In the next step, the analog circuit 1 is transferred 502 to a test state of the test states by setting and adopting this test state, whereby the measuring device preferably carries out this transfer and the setting by means of the test logic 38, for example via a JTAG test bus interface, whereupon the analog circuit 1 adopts this test state.

In the following step a), the current consumption of the analog circuit 1 in this test state is detected 503 and a current consumption value is determined, in particular by means of the measuring device, which preferably detects a value of the electric current that it feeds into one of the supply voltage lines 3, 8 of the analog circuit 1.

In the following step b), the detected current consumption value is compared 504 with a specified value, which may be specific to the set test state, with the said measuring device preferably performing this comparison.

In the following step c), the analog circuit 1 is transferred 508 to a further test state of the test states by setting and assuming this further test state, wherein this further test state differs from the previously assumed test states of the test states and wherein, in particular, the transfer 508 and the setting are performed by means of the measuring device, and the continuation of the method with step a) until all test states or a predetermined subset of the test states have been assumed;

Therefore, a check 509 is performed to determine whether all test states or all test states specified to be taken have been taken. If all test states to be assumed have been assumed, the procedure 507 is terminated and, if applicable, the analog circuit 1 is used as intended. If not all test states to be assumed have been assumed, the procedure is continued at step a) with the detection 503 of the current consumption of the analog circuit 1.

The intended use 507 of analog circuit 1 naturally requires that no errors within the meaning of this document have been or are detected during any previous and/or subsequent tests and/or during operation of the analog circuit.

In step d), which follows the comparison 504 of the current consumption value with a specified value, the circuit is closed 505 to indicate an error if the current consumption value exceeds the specified value, whereby the said measuring device preferably makes this determination and then preferably rejects the analog circuit 1 in the event of such an error 506.

The closing 505 for an error can swap the order with the transfer 508 of the analog circuit 1 to a further test state of the test states.

The check 509 as to whether all test states or all specified test states to be entered have been entered can swap the order with the transfer 508 of the analog circuit 1 to a further test state of the test states.

In this respect, the numbering of steps a) to d) here in the description and in the claims does not imply any chronological order.

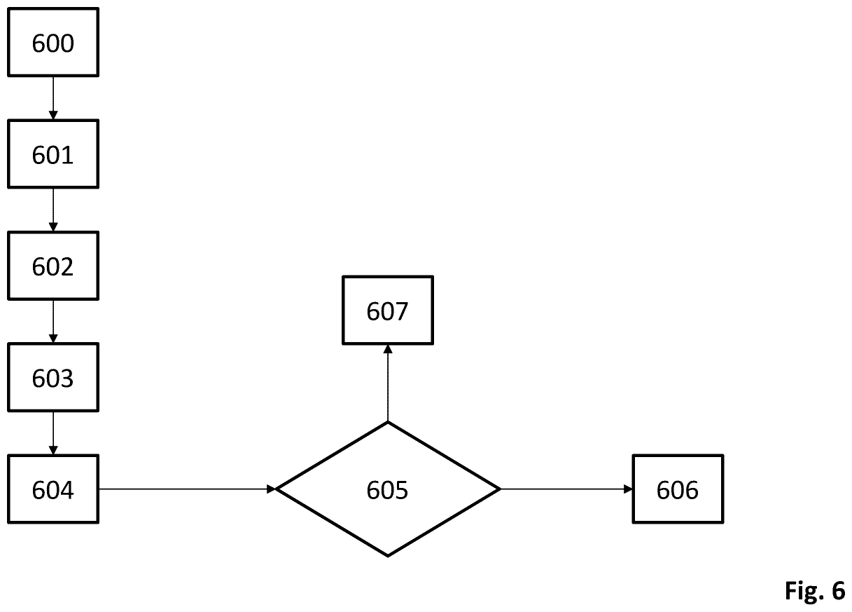

The present document proposes a further method for performing an IDDQ test on an analog circuit 1 to solve the above problem. FIG. 6 illustrates the method schematically and in simplified form. The analog circuit 1 is, for example, an analog circuit 1 corresponding to the embodiment shown in FIG. 2.

The method proposed here comprises several steps.

If no measuring device is available, the method begins with step 600 of providing a measuring device.

In the next step, the analog circuit 1 is supplied with electrical energy, preferably by the measuring device.

In the next step, the analog circuit 1 is transferred 602 to the first test state, whereby the measuring device preferably carries out this transfer by means of the test logic 38, for example via a JTAG test bus interface, and preferably controls it.

In the next step, the current consumption of analog circuit 1 is detected 503 in this first test state and a current consumption value is determined, in particular by means of the measuring device, which preferably detects a value of the electric current that it feeds into one of the supply voltage lines 3, 8 of analog circuit 1.

In the next step, the determined current consumption value is compared 604 with a specified value, with the said measuring device preferably performing this comparison.

In the next step, a fault is detected 605 if the current consumption value is greater than the specified value, with the said measuring device preferably performing this detection and then preferably rejecting 606 the analog circuit 1, which may be faulty, in the event of such a fault.

If the measuring device does not detect an error in analog circuit 1 in the preceding step 605, analog circuit 1 is more likely to be used as intended 607 if analog circuit 1 is not rejected for other reasons in further, subsequent, or preceding tests.

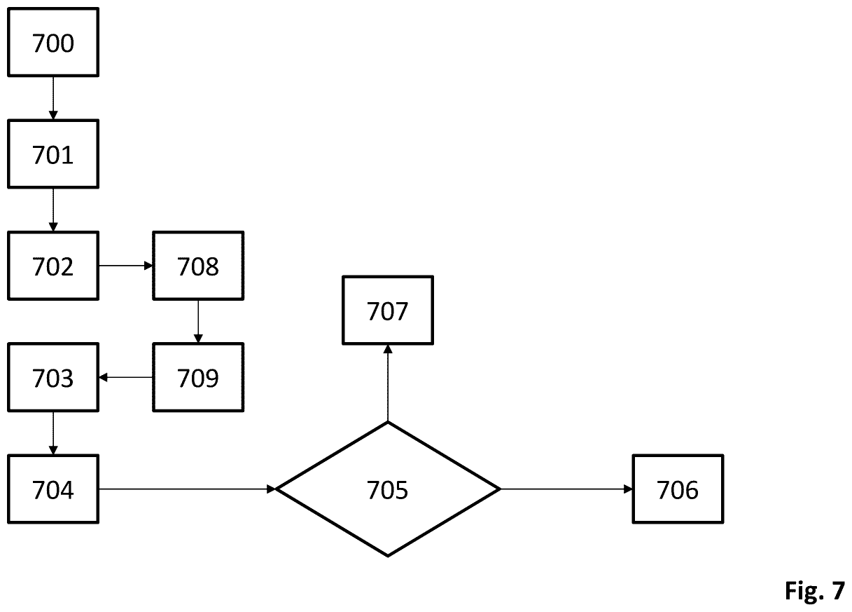

The present document further proposes a method for performing a stress test on an analog circuit 1 to solve the above problem. FIG. 7 illustrates the method in a simplified schematic form. The analog circuit 1 is, for example, an analog circuit corresponding to the embodiment shown in FIG. 2.

The method proposed here comprises several steps.

If no measuring device is available, the method begins with step 700 of providing a measuring device.

In the next step, the analog circuit 1 is supplied with electrical energy, preferably by the measuring device.

In the next step, the analog circuit 1 is transferred 702 to the first test state, with the measuring device preferably performing this transfer by means of the test logic 38, for example via a JTAG test bus interface.

In the next step, the supply voltage is increased 708 for a predetermined period of time by a predetermined stress voltage value, with the measuring device preferably performing this increase 708.

Reversing 709 the increase 708 in the supply voltage, wherein the measuring device preferably performs this reversal of the increase 708;

In the next step, the current consumption of the analog circuit 1 is detected 703 in this first test state and a current consumption value is determined, in particular by means of the measuring device, which preferably detects a value of the electric current that it feeds into one of the supply voltage lines 3, 8 of the analog circuit 1.

In the next step, the detected current consumption value is compared 704 with a specified value, with the said measuring device preferably performing this comparison.

In the next step, a fault is detected 705 if the current consumption value is greater than the specified value, with the said measuring device preferably performing this detection and then preferably rejecting the analog circuit 1, if faulty, in the event of such a fault 706.

If the measuring device does not conclude that there is a fault in the analog circuit 1 in the previous step 705, the analog circuit 1 can be used as intended 707 with a higher probability if the analog circuit 1 is not rejected for other reasons in further, subsequent, or preceding tests.

### Advantage

The use of the proposed switches and tri-state gates for setting special test states can enable a meaningful IDDQ test of the exemplary analog circuit 1. This increases the testability of the exemplary analog circuit 1 and thus the delivery quality.

In contrast to the technical teaching of US 2005/0024075A1, the technical teaching presented here solves the problem of IDDQ testability of an analog circuit. In contrast to the examples of US 2005/0024075A1, the technical teaching presented here discloses a solution that is fully IDDQ testable. Fully refers here to an IDDQ test of ALL analog transistors in the example presented here.

In contrast to the technical teaching of US 2005/0024075A1, the technical teaching of the present proposal does not exhibit any static current paths between the positive and negative supply voltages in the test state.

In contrast to the technical teaching of US 2005/0024075A1, the document presented here proposes reconfiguring the analog circuit to be tested into a digital circuit. In contrast to the technical teaching of US 2005/0024075A1, the technical teaching of the document presented here enables the fully automatic generation of IDDQ test patterns. The use of the technical teaching of the document presented here can, therefore, enable the generation of evidence in accordance with the requirements of ISO 26262.

In contrast to the technical teaching of US 2005/0024075A1, the document presented here proposes a separation of the feedback branches.

In contrast to the technical teaching of US 2005/0024075A1, the document presented here proposes a complete disconnection of the control nodes. In the example shown in FIG. 2 of the document presented here, this is achieved in particular by the exemplary switches S6, S7, S8, S1, S2, S3, and S4. In contrast, the technical teaching of US 2005/0024075A1 does not provide for such additional transfer gates for testing purposes.

In contrast to US 2005/0024075A1, the document presented here thus discloses a circuit that is testable in the test state IDDQ and, in addition, its principles for transfer to other analog circuits.

### LIST OF REFERENCE SYMBOLS

1 example analog circuit;
2 voltage source;
3 Supply voltage line;
4 Current source;
5 Reference current;
6 first node;
7 first transistor;
8 reference potential line;
9 second transistor;
10 third transistor;
11 fourth transistor;
12 fifth transistor;
13 sixth transistor;
14 second node;
15 seventh transistor;
16 eighth transistor;
17 inverter;
18 digital transport clock;
19 Inverted digital transport clock;
20 ninth transistor;
21 Tenth transistor;
22 eleventh transistor;
23 twelfth transistor;
24 analog output and input node of a subsequent circuit;
25 Intermediate node;
26 Output of the source follower from the seventh transistor 15 and eighth transistor 16;
27 Reference voltage between first node 6 and reference potential line 8;
28 Control electrode of the third transistor 10;
29 Control electrode of the fourth transistor 11;
30 thirteenth transistor;
31 third node;
32 fourth node;
33 control electrode 33 of the first transistor 7;
34 Control electrode of the second transistor 9;
36 Control electrode of the fifth transistor 12;
37 Control electrode of the eighth transistor 16;
38 Test logic;
39 Control electrode of the sixth transistor 13;
40 other control signals of the overall circuit of which the exemplary analog circuit 1 is a part;
41 modified digital transport clock;
42 modified inverted digital transport clock;
43 Control electrode of the thirteenth transistor 30;
400 Provision of a measuring device;
401 Supplying electrical power to the analog circuit 1;
402 Transferring 402 the analog circuit 1 to the first test state;
403 Detecting the current consumption of analog circuit 1 in a test state and determining a current consumption value, in particular by means of a measuring device;
404 Comparing the current consumption value with a specified value,
405 Concluding that there is a fault;
406 Rejecting a faulty analog circuit 1;
407 Termination of the process and, if applicable, intended use of analog circuit 1;
500 Provision of a measuring device;
501 Supplying the analog circuit 1 with electrical energy;
502 Transferring 502 the analog circuit 1 to a test state of the test states by setting and adopting this test state;
503 Detecting the current consumption of analog circuit 1 in a test state and determining a current consumption value, in particular by means of a measuring device;
504 Comparing the current consumption value with a specified value,
505 Concluding that there is a fault;
506 Rejecting a faulty analog circuit 1;
507 Termination of the process and, if applicable, intended use of analog circuit 1;
508 Transferring the analog circuit 1 to a further test state of the test states by setting and entering this further test state;
509 Check 509 whether all test states or all test states specified to be entered have been entered;
600 Providing a measuring device;
601 Supplying electrical power to analog circuit 1;
602 Transferring 602 the analog circuit 1 to the first test state;
603 Detecting the current consumption of analog circuit 1 in a test state and determining a current consumption value, in particular by means of a measuring device;
604 Comparing the current consumption value with a specified value,
605 Concluding that there is a fault;
606 Rejecting a faulty analog circuit 1;
607 Termination of the process and, if applicable, intended use of analog circuit 1;
700 Provision of a measuring device;
701 Supplying the analog circuit 1 with electrical energy;
702 Transferring 402 the analog circuit 1 to the first test state;
703 Detecting the current consumption of analog circuit 1 in a test state and determining a current consumption value, in particular by means of a measuring device;
704 Comparing the current consumption value with a specified value;
705 Concluding that there is a fault;
706 Rejecting a faulty analog circuit 1;
707 Termination of the procedure and, if applicable, intended use of analog circuit 1;
708 Increase the supply voltage;
709 Reversing the increase in supply voltage, which may be done in whole or in part;
G1 first tri-state gate;
G2 second tri-state gate;
G3 third tri-state gate;
G4 fourth tri-state gate;
G5 fifth tri-state gate;
G6 sixth tri-state gate;
G7 seventh tri-state gate;
G8 eighth tri-state gate;
G9 ninth tri-state gate;
S1 first switch;
S2 second switch;
S3 third switch;
S4 fourth switch;
S5 fifth switch;
S6 sixth switch;
S7 seventh switch;
S8 eighth switch;
S9 ninth switch;
Idd Supply current into analog circuit 1;

### LIST OF CITED DOCUMENTS

If an application for a property right claiming priority of the document submitted here is filed in a country that allows the technical teaching of cited documents to be claimed in combination with the technical teaching of this document as part of the disclosure of this document, the following documents are expressly part of this disclosure in combination with the document submitted here.

### PATENT LITERATURE

US 2005/0024075A1

### NON-PATENT LITERATURE

NPL1: https://de.wikipedia.org/wiki/Boundary_Scan_Test (downloaded on February 11, 2022)
NPL2: L. Y. Ungar, H. Bleeker, J. E. McDermid and H. Hulvershorn, “IEEE-1149.x standards: achievements vs. expectations,” 2001 IEEE Autotestcon Proceedings. IEEE Systems Readiness Technology Conference. (Cat. No.01CH37237), 2001, pp. 188-205, doi: 10.1109/AUTEST.2001.948964
NPL3: “IEEE Standard for Boundary-Scan Testing of Advanced Digital Networks,” in IEEE Std 1149.6-2015 (Revision of IEEE Std 1149.6-2003), vol., no., pp. 1-230, 18 March 2016, doi: 10.1109/IEEESTD.2016.7436703.
NPL4: “IEEE Standard for Reduced-Pin and Enhanced-Functionality Test Access Port and Boundary-Scan Architecture,” in IEEE Std 1149.7-2009, vol., no., pp. 1-985, Feb. 10, 2010, doi: 10.1109/IEEESTD.2010.5412866.
NPL5: “IEEE Standard for Test Access Port and Boundary-Scan Architecture-Redline,” in IEEE Std 1149.1-2013 (Revision of IEEE Std 1149.1-2001)-Redline, vol., no., pp. 1-899, May 13, 2013.
NPL6: “IEEE Standard for Test Access Port and Boundary-Scan Architecture,” in IEEE Std 1149.1-2013 (Revision of IEEE Std 1149.1-2001), vol., no., pp. 1-444, May 13, 2013, doi: 10.1109/IEEESTD.2013.6515989.
NPL7: “IEEE Standard for a Mixed-Signal Test Bus,” in IEEE Std 1149.4-2010 (Revision of IEEE Std 1149.4-1999), vol., no., pp. 1-116, March 18, 2011, doi: 10.1109/IEEESTD.2011.5738198.
NPL8: “IEEE Standard for Boundary-Scan-Based Stimulus of Interconnections to Passive and/or Active Components,” in IEEE Std 1149.8.1-2012, vol., no., pp. 1-95, Aug. 9, 2012, doi: 10.1109/IEEESTD.2012.6259815.
NPL9: “IEEE Standard for High-Speed Test Access Port and On-Chip Distribution Architecture,” in IEEE Std 1149.10-2017, vol., no., pp. 1-96, July 28, 2017, doi: 10.1109/IEEESTD.2017.7995164.
NPL10: “IEEE Standard for Boundary-Scan Testing of Advanced Digital Networks-Redline,” in IEEE Std 1149.6-2015 (Revision of IEEE Std 1149.6-2003)—Redline, vol., no., pp. 1-441, March 18, 2016.
NPL11: “IEEE Standard for Access and Control of Instrumentation Embedded within a Semiconductor Device,” in IEEE Std 1687-2014, vol., no., pp. 1-283, Dec. 5, 2014, doi: 10.1109/IEEESTD.2014.6974961.
NPL12: “IEEE Draft Standard for Reduced-Pin and Enhanced-Functionality Test Access Port and Boundary-Scan Architecture,” in IEEE P1149.7/D6, July 2020, vol., no., pp. 1-1043, Nov. 3, 2020.
NPL13: G. O. D. Acevedo and J. Ramirez-Angulo, “VDDQ: a built-in self-test scheme for analog on-chip diagnosis, compliant with the IEEE 1149.4 mixed-signal test bus standard,” Proceedings of the Fourth IEEE International Caracas Conference on Devices, Circuits and Systems (Cat. No.02TH8611), 2002, pp. I026-I026, doi: 10.1109/ICCDCS.2002.1004083.
NPL14: “IEEE Draft Standard for a Mixed-Signal Test Bus,” in IEEE P1149.4/D2, September 2010, vol., no., pp. 1-113, 7 Oct. 2010.
NPL15: “IEEE Approved Draft Standard for Test Access Architecture for Three-Dimensional Stacked Integrated Circuits,” in IEEE P1838_D 3.00, September 2019, vol., no., pp. 1-63, 7 Nov. 2019.
NPL16: Dietmar Ehrhardt, “Integrated Analog Circuit Technology: Technology, Design, Simulation, and Layout,” Jun. 28, 2000, Vieweg Verlagsgesellschaft; 2000. Edition (June 28, 2000), ISBN-10: 3528038608, ISBN-13: 978-352803860
NPL17: Phillip E. Allen (author), Douglas R. Holberg, “CMOS Analog Circuit Design,” Oxford University Press; 3rd edition. International (July 13, 2012), ISBN-10: 0199937427, ISBN-13: 978-0199937424
NPL18: Saggio, Giovanni, Tor Vergata, “Principles of Analog Electronics”, ASIN: 1466582014, Taylor &amp; Francis Inc, January 29, 2014, ISBN-10: 9781466582019, ISBN-13: 978-1466582019
NPL19: Ulrich Tietze, Christoph Schenk, “Halbleiter-Schaltungstechnik” Hardcover—July 5, 2019, Springer Vieweg; 16th, expanded and updated edition 2019, ISBN-10: 3662485532, ISBN-13: 978-3662485538
NPL20: Ian A. Grout, “Integrated Circuit Test Engineering: Modern Techniques” Springer London; 2006. Edition, June 2, 2010, ISBN-10: 1846280230, ISBN-13: 978-1846280238
NPL21: Wikipedia https://en.wikipedia.org/wiki/Iddq_testing.
NPL22: ISO26262

What is claimed is:

1. An analog circuit based on MOS, BiCMOS, or CMOS;
wherein the analog circuit is designed to fulfill a predetermined circuit purpose in a normal state of the analog circuit,
wherein the analog circuit has one or more input signals and/or one or more output signals,
wherein the analog circuit has at least one analog signal within the analog circuit
wherein the analog circuit is coupled to a test logic,
wherein the test logic is designed to set the analog circuit to the normal state and at least a first test state,
wherein the analog circuit comprises first components (7, 9, 10, 11, 12, 13, 15, 16, 20, 21, 22, 23, 30),
wherein the first components (7, 9, 10, 11, 12, 13, 15, 16, 20, 21, 22, 23, 30) are designed to perform a function of the analog circuit in accordance with the predetermined circuit purpose of the analog circuit in the normal state of the analog circuit,
wherein the first components (7, 9, 10, 11, 12, 13, 15, 16, 20, 21, 22, 23, 30) each have a control electrode,
wherein the first components (7, 9, 10, 11, 12, 13, 15, 16, 20, 21, 22, 23, 30) are designed to also be operated as switches by their respective control electrodes,
wherein the first components (7, 9, 10, 11, 12, 13, 15, 16, 20, 21, 22, 23, 30) in a respective operation as switches each have an on state and an off state as respective switching states,
wherein the first components (7, 9, 10, 11, 12, 13, 15, 16, 20, 21, 22, 23, 30) are fully switched on in the on state,
wherein the first components (7, 9, 10, 11, 12, 13, 15, 16, 20, 21, 22, 23, 30) are fully switched off in the off state,
wherein the analog circuit comprises second components (S1 to S9; G1 to G9),
wherein the test logic is designed to use the second components (S1 to S9; G1 to G9) in the first test state of the analog circuit to set the switching states of at least one first component (7, 9, 12, 16) of the first components (7, 9, 10, 11, 12, 13, 15, 16, 20, 21, 22, 23, 30),
wherein the control electrode (33, 34, 36, 37) of the at least one first component (7, 9, 12, 16) of the first components (7, 9, 10, 11, 12, 13, 15, 16, 20, 21, 22, 23, 30) is not directly connected to an input signal or not directly connected to an output signal,
wherein the test logic is designed to switch this control electrode (33, 34, 36, 37) of the at least one first component (7, 9, 12, 16) of the first components (7, 9, 10, 11, 12, 13, 15, 16, 20, 21, 22, 23, 30) in the first test state from the rest of the analog circuit by use of at least one switch (S1, S2, S3, S4),
wherein the test logic is designed to connect the control electrodes (33, 34, 36, 37) of the at least one first component (7, 9, 12, 16) of the first components (7, 9, 10, 11, 12, 13, 15, 16, 20, 21, 22, 23, 30) from the rest of the analog circuit by use of the at least the switch (S1, S2, S3, S4) in the normal state,
wherein the test logic is designed to connect, in the first test state, this control electrode (33, 34, 36, 37, 39) of the at least one first component (7, 9, 12, 16) of the first components (7, 9, 10, 11, 12, 13, 15, 16, 20, 21, 22, 23, 30) by use of at least one first means (G1, G2, G5, G6) in an on state or to switch them off in an off state, and
wherein the test logic is designed to control the at least one first means (G1, G2, G5, G6) in the normal state such that the at least one first means (G1, G2, G5, G6) switches the control electrode (33, 34, 36, 37, 39) of the at least one first component (7, 9, 12, 16) of the first components (7, 9, 10, 11, 12, 13, 15, 16, 20, 21, 22, 23, 30) in the normal state of the analog circuit.

2. The analog circuit according to claim 1, wherein:
the analog circuit comprises N-channel transistors (7, 9, 16, 30, 10, 11, 20, 22) and P-channel transistors (12, 13, 15, 21, 23), and
the second components (S1 to S9; G1 to G9) are designed to enable the test logic to set the switching states of the first components (7, 9, 10, 11, 12, 13, 15, 16, 20, 21, 22, 23, 30) in such a way that:
that in the first test state of the analog circuit either all N-channel transistors (7, 9, 16, 30, 10, 11, 20, 22) of the analog circuit are blocked and all P-channel transistors (12, 13, 15, 21, 23) of the analog circuit conduct, or
in the first test state of the analog circuit, all N-channel transistors (7, 9, 16, 30, 10, 11, 20, 22) of the analog circuit conduct and all P-channel transistors (12, 13, 15, 21, 23) of the analog circuit are blocked.

3. The analog circuit according to claim 1, wherein:
the analog circuit has a positive supply voltage line,
the analog circuit has a negative supply voltage line and
the analog circuit has several possible current paths from the positive supply voltage line to the negative supply voltage line through at least one component of the first components (7, 9, 10, 11, 12, 13, 15, 16, 20, 21, 22, 23, 30) and/or the second components (S1 to S9; G1 to G9),
wherein the second components (S1 to S9; G1 to G9) are designed to enable the setting of the switching states of the first components (7, 9, 10, 11, 12, 13, 15, 16, 20, 21, 22, 23, 30) in such a way that in each current path of these possible current paths at least one first component (7, 9, 10, 11, 12, 13, 15, 16, 20, 21, 22, 23, 30) and/or at least one second component (S1 to S9; G1 to G9) blocks.

4. The analog circuit according to claim 3, wherein:
in at least one current path of the possible current paths, hereinafter referred to as the current path under consideration, exactly one first component or exactly one second component blocks in the first test state,
the exactly one first component or exactly one second component corresponds to exactly one blocking first component or exactly one blocking second component in the current path under consideration to an IDDQ component, and
the other components that are different from the IDDQ component do not block in this considered current path in the first test state.

5. A method for performing an IDDQ test of an analog circuit according to claim 4 comprising:
providing a measuring device;
supplying the analog circuit with electrical energy;
transferring the analog circuit to the first test state;
detecting a current consumption of the analog circuit in the first test state and determining a current consumption value by the measuring device;
comparing the current consumption value with a specified value; and
concluding that there is a fault if the current consumption value is above the specified value.

6. A method for performing an IDDQ test of an analog circuit according to claim 4,
wherein the analog circuit has one or more further test states in addition to a the first test state,
wherein these further test states and the first test state are hereinafter referred to collectively as the test states,
wherein the test states differ from one another in that an IDDQ component of one test state of the test states differs from another IDDQ component of another test state of the test states, and
wherein the method comprises:
providing a measuring device;
supplying the analog circuit with electrical energy;
transferring the analog circuit to a test state of the test states by setting and adopting the test state by the measuring device;
in a step a, detecting a current consumption of the analog circuit in the set test state and determining a current consumption value by means of the measuring device;
in a step b, comparing the determined current consumption value with a specified value, which may be specific to the set test state;
in a step c, transferring the analog circuit to a further test state of the test states by setting and adopting this further test state, wherein this further set test state differs from previously adopted test states of the test states and wherein the transfer is carried out by means of the measuring device, and continuing with step a until all test states or a predetermined subset of the test states have been assumed; and
in a step d, closing for a fault if the determined current consumption value is above the specified value, wherein step d can also be performed between step b and step c and wherein the measuring device can also perform this closing for the fault.

7. A method for performing an IDDQ test of an analog circuit according to claim 2, comprising:
providing a measuring device;
supplying the analog circuit with electrical energy, wherein the measuring device can also perform this supply;
transferring the analog circuit to the first test state, wherein the measuring device can also control this transfer;
detecting a current consumption of the analog circuit in the first test state and determining a current consumption value, wherein the measuring device can also perform this detection;
comparing the detected current consumption value with a specified value, whereby the measuring device can also perform this comparison; and
concluding that there is a fault if the detected current consumption value is above the specified value, wherein the measuring device can also perform this conclusion that there is a fault.

8. A method for performing a stress test on an analog circuit according to claim 2 comprising:
providing a measuring device;
supplying the analog circuit with electrical energy;
transferring the analog circuit to a first test state;
increasing a supply voltage for a predetermined period of time by a predetermined stress voltage value;
reversing the increase in the supply voltage;
detecting a current consumption of the analog circuit in this first test state and determining a current consumption value by means of the measuring device;
comparing the current consumption value with a specified value; and
concluding that there is a fault if the current consumption value is above the specified value.

9. A method for performing an IDDQ test of an analog circuit according to claim 4, comprising:
providing a measuring device;
supplying the analog circuit with electrical energy, wherein the measuring device can also perform this supply;
transferring the analog circuit to the first test state, wherein the measuring device can also control this transfer;
detecting a current consumption of the analog circuit in the first test state and determining a current consumption value, wherein the measuring device can also perform this detection;
comparing the detected current consumption value with a specified value, whereby the measuring device can also perform this comparison; and
concluding that there is a fault if the detected current consumption value is above the specified value, wherein the measuring device can also perform this conclusion that there is a fault.

10. A method for performing a stress test on an analog circuit according to claim 4, comprising:
providing a measuring device;
supplying the analog circuit with electrical energy;
transferring the analog circuit to a first test state;
increasing a supply voltage for a predetermined period of time by a predetermined stress voltage value;
reversing the increase in the supply voltage;
detecting a current consumption of the analog circuit in this first test state and determining a current consumption value by means of the measuring device;
comparing the current consumption value with a specified value; and
concluding that there is a fault if the current consumption value is above the specified value.

11. The analog circuit according to claim 1, wherein each respective first means of the at least one first means is a tri-state driver.
